(19) United States
(12) Patent Application Publication
(10) Pub. No.: US 2015/0145610 A1
(43) Pub. Date: May 28, 2015

(54) PACKAGED DEVICE WITH ACOUSTIC RESONATOR AND ELECTRONIC CIRCUITRY AND METHOD OF MAKING THE SAME

(71) Applicant: Avago Technologies General IP (Singapore) Pte. Ltd., Singapore (SG)

(72) Inventors: Richard Ruby, Menlo Park, CA (US); Martha Small, Fort Collins, CO (US)

(21) Appl. No.: 14/607,010

(22) Filed: Jan. 27, 2015

Related U.S. Application Data
(63) Continuation-in-part of application No. 13/162,883, filed on Jun. 17, 2011.
(60) Provisional application No. 61/932,722, filed on Jan. 28, 2014.

(51) Int. Cl. H03H 9/10; H03B 5/04; H03B 5/36; H03H 9/17; H03H 9/25

(52) U.S. Cl. CPC H03H 9/10; H03H 9/17; H03H 9/25; H03B 5/36; H03B 5/04
USPC 331/107 R; 310/321; 310/313 R

(57) ABSTRACT

A device includes: a base substrate having a bonding pad and a peripheral pad, the peripheral pad encompassing the bonding pad; an acoustic resonator on the base substrate; a cap substrate having a bonding pad seal and a peripheral pad seal, the bonding pad seal bonding around the perimeter of the bonding pad and the peripheral pad seal bonding with the peripheral pad to define a sealed volume between the cap substrate and the base substrate, the cap substrate having a through hole therein over the bonding pad providing access for a connection to the bonding pad; a low-resistivity material layer region disposed on a portion of a surface of the cap substrate disposed inside the sealed volume, the material layer region being isolated from the bonding pad seal; and electronic circuitry disposed in the material layer region and electrical connected with the acoustic resonator.

### CROSS-REFERENCE TO RELATED APPLICATIONS

The present application claims priority under 35 U.S.C. §119(e) from U.S. Provisional Application No. 61/932,722 entitled “LOW JITTER DEVICE AND SYSTEM”, filed on Jan. 28, 2014. The disclosure of this provisional application is hereby specifically incorporated herein by reference. The present application is also a continuation-in-part of and claims priority under 35 U.S.C. §120 from U.S. patent application Ser. No. 13/162.883 entitled “CAPACITANCE DETECTOR FOR ACCELEROMETER AND GYROSCOPE AND ACCELEROMETER AND GYROSCOPE WITH CAPACITANCE DETECTOR” to Richard Ruby and filed on Jun. 17, 2011. The disclosure of this parent application is hereby specifically incorporated herein by reference.

### BACKGROUND

Small acoustic components, including specifically acoustic transducers and resonators, are being employed in a number of devices, including for example, oscillators. Acoustic transducers and resonators are manufactured using a variety of different technologies, including for example film bulk acoustic wave (FBAR) devices. Acoustic components are typically manufactured on substrates separate from device electronics due to incompatibilities in both processing and substrate requirements. The substrate for an acoustic device such as FBAR must have very high resistivity to avoid substrate coupling to the resonator. Semiconductor devices (e.g., transistors) require much lower resistivity in the device region. In the past, acoustic components have been manufactured, for example, with processes where the acoustic component is placed in a metal, ceramic, or plastic package and a lid is bonded to the package. In a typical configuration, an electrical connection between the acoustic component and the rest of the electronic circuitry for a device (e.g., an oscillator) is provided through a lead or wire from the package to an external circuit board to which the packaged acoustic resonator is attached or connected, and on which the rest of the electronic circuitry of the device is provided.

However, an electrical signal transmitted via the lead or wire between such a packaged acoustic component and external electronic circuitry is subject to loss, noise and/or interference due to the interconnect lead length, all of which can degrade the performance characteristics of the device.

What is needed, therefore, is an improved packaging arrangement and method for devices, particularly devices that include electronic circuitry and acoustic devices.

### BRIEF DESCRIPTION OF THE DRAWINGS

Representative embodiments are best understood from the following detailed description when read with the accompanying drawing figures. It is emphasized that the various features are not necessarily drawn to scale. In fact, the dimensions shown in the drawings may be arbitrarily increased or decreased for clarity of discussion. Wherever applicable and practical, like reference numerals refer to like elements.

FIG. 1 shows a cross-sectional view of a packaged device according to a representative embodiment.

FIG. 2 shows a cross-sectional view of a packaged device in accordance with another representative embodiment.

FIG. 3 shows a cross-sectional view of a packaged device in accordance with another.

FIG. 4 shows a cross-sectional view of a portion of a packaged FMOS device, in accordance with a representative embodiment.

FIG. 5 shows a top cutaway view of a packaged FMOS device in accordance with a representative embodiment.

FIGS. 6A-B show a base substrate and a lid substrate, respectively, of the packaged FMOS device depicted in FIG. 5.

FIG. 7 shows a cross-sectional view of a packaged FMOS device with two FBAR resonators, in accordance with a representative embodiment.

FIG. 8 shows a cross-sectional view of a temperature compensated oscillator of the packaged device, in accordance with a representative embodiment.

FIG. 9 is a simplified schematic block diagram of a temperature compensated oscillator in accordance with a representative embodiment.

FIG. 10 shows measured phase noise plots of an FMOS oscillator for four temperatures.

FIG. 11 shows a cross-sectional view of a packaged device in accordance with another representative embodiment.

### DETAILED DESCRIPTION

In the following detailed description, for purposes of explanation and not limitation, representative embodiments disclosing specific details are set forth in order to provide a thorough understanding of an embodiment according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the representative embodiments. Such methods and apparatuses are clearly within the scope of the present teachings.

Unless otherwise noted, when a first device is said to be connected to a second device, this encompasses cases where one or more intermediate devices may be employed to connect the two devices to each other. However, when a first device is said to be directly connected to a second device, this encompasses only cases where the two devices are connected to each other without any intermediate or intervening devices. Similarly, when a signal is said to be coupled to a device, this encompasses cases where one or more intermediate devices may be employed to couple the signal to the device. However, when a signal is said to be directly coupled to a device, this encompasses only cases where the signal is directly coupled to the device without any intermediate or intervening devices. As used herein. “approximately” means within 10%. As used herein, when a first structure, material, or layer is to cover a second structure, material, or layer, this includes cases where the first structure, material, or layer substantially or completely encases or surrounds the second structure, material or layer.

It is to be understood that the terminology used herein is for purposes of describing particular embodiments only, and is not intended to be limiting. Any defined terms are in addition to the technical and scientific meanings of the defined terms as commonly understood and accepted in the technical field of the present teachings.

As used in the specification and appended claims, the terms ‘a’, ‘an’ and ‘the’ include both singular and plural referents, unless the context clearly dictates otherwise. Thus, for example, ‘a device’ includes one device and plural devices.

As used in the specification and appended claims, and in addition to their ordinary meanings, the terms ‘substantial’ or ‘substantially’ mean to with acceptable limits or degree. For example, ‘substantially cancelled’ means that one skilled in the art would consider the cancellation to be acceptable.

As used in the specification and the appended claims and in addition to its ordinary meaning, the term ‘approximately’ means to within an acceptable limit or amount to one having ordinary skill in the art. For example, ‘approximately the same’ means that one of ordinary skill in the art would consider the items being compared to be the same.

Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be “below” that element. Similarly, if the device were rotated by 90° with respect to the view in the drawings, an element described “above” or “below” another element would now be “adjacent” to the other element, where “adjacent” means either abutting the other element, or having one or more layers, materials, structures, etc., between the elements.

Specific embodiments of electronic devices, and methods of making such devices, will now be described below in the specific context of devices (e.g., oscillators) employing acoustic resonators, where the disclosed packaging arrangements and methods of manufacture have particular benefits. In some representative embodiments, first and second oscillators may each include an acoustic resonator. As described more fully below, the acoustic resonator may be bulk acoustic wave (BAW) resonator, which may be a film bulk acoustic resonator (FBAR), or a solidly mounted resonator (SMR), and variations of an FBAR or an SMR, such as a temperature compensated BAW resonator, sometimes referred to as a zero drift resonator (ZDR). However, the acoustic resonators contemplated for use in the representative embodiments are not limited to BAW resonators, as surface acoustic wave (SAW) resonators may be included in certain packaged devices of representative embodiments described below. It is noted, however, that the packaging of various electronic components and methods of manufacture described below have applicability and benefits for a wide variety of electronic devices other than the representative embodiments described below.

When connected in a selected topology, a plurality of the BAW resonators can act as an electrical filter. For example, the acoustic resonators may be arranged in a ladder-filter or lattice-filter arrangement, such as described in U.S. Pat. No. 5,910,756 to Ella, and U.S. Pat. No. 6,262,637 to Bradley, et al., the disclosures of which are specifically incorporated herein by reference. The electrical filters may be used in a number of applications, such as in duplexers, diplexers, triplexers, quadplexers, quintplexers, etc.

A variety of materials and methods of fabrication are contemplated for the BAW resonators of the apparatuses of the present teachings. Various details of such devices and corresponding methods of fabrication may be found, for example, in one or more of the following U.S. patent publications: U.S. Pat. No. 6,107,721, to Lakin; U.S. Pat. Nos. 5,587,620, 5,873,153, 6,507,983, 7,388,454, 7,629,865, 7,714,684 to Ruby et al.; U.S. Pat. Nos. 7,791,434 8,188,810, and 8,230,562 to Fazzio, et al.; U.S. Pat. No. 7,280,007 to Feng et al.; U.S. Pat. No. 8,248,185 to Choy, et al.; U.S. Pat. No. 7,345,410 to Grannen, et al.; U.S. Pat. No. 6,828,713 to Bradley, et al.; U.S. Pat. No. 7,561,009 to Larson, et al.; U.S. Patent Application Publication No. 20120326807 to Choy, et al.; U.S. Patent Application Publication No. 20100327994 to Choy, et al.; U.S. Patent Application Publications Nos. 20110180391 and 20120177816 to Larson 111, et al.; U.S. Patent Application Publication No. 20070205850 to Jamneala et al.; U.S. Patent Application Publication No. 20110266925 to Ruby, et al.; U.S. Patent Application Publication Nos. 20140292149 and 20140292150 to Zhou, et al.; U.S. patent application Ser. No. 14/161,564 entitled: “Method of Fabricating Rare-Earth Element Doped Piezoelectric Material with Various Amounts of Dopants and a Selected C-Axis Orientation,” filed on Jan. 22, 2014 to John L. Larson III; U.S. patent application Ser. No. 13/662,460 entitled “Bulk Acoustic Wave Resonator having Piezoelectric Layer with Multiple Dopants,” filed on Oct. 27, 2012 to Choy, et al.; U.S. patent application Ser. No. 13/906,873 entitled “Bulk Acoustic Wave Resonator having Piezoelectric Layer with Varying Amounts of Dopants” to John Choy, et al. and filed on May 31, 2013; and U.S. patent application Ser. No. 14/191,771, entitled “Bulk Acoustic Wave Resonator having Doped Piezoelectric Layer” to Feng, et al. and filed on Feb. 27, 2014. The entire disclosure of each of the patents, published patent applications and patent applications listed above are hereby specifically incorporated by reference herein. It is emphasized that the components, materials and methods of fabrication described in these patents and patent applications are representative and other methods of fabrication and materials within the purview of one of ordinary skill in the art are also contemplated.

In a beneficial arrangement, a packaged device may be provided using methods and devices disclosed in commonly-owned U.S. Pat. No. 8,232,845, and U.S. patent application Ser. No. 13/162,883 filed on Jun. 17, 2011, the disclosures of which are hereby incorporated herein by references as if fully set forth herein.

Specific embodiments of electronic devices, and methods of making such devices, will now be described below in the specific context of devices (e.g., oscillators) employing acoustic resonators, where the disclosed packaging arrangements and methods of manufacture have particular benefits. However it should be understood that the packaging arrangements and methods of manufacture described below have applicability and benefits for a wide variety of electronic devices other than the specific representative embodiments described below.

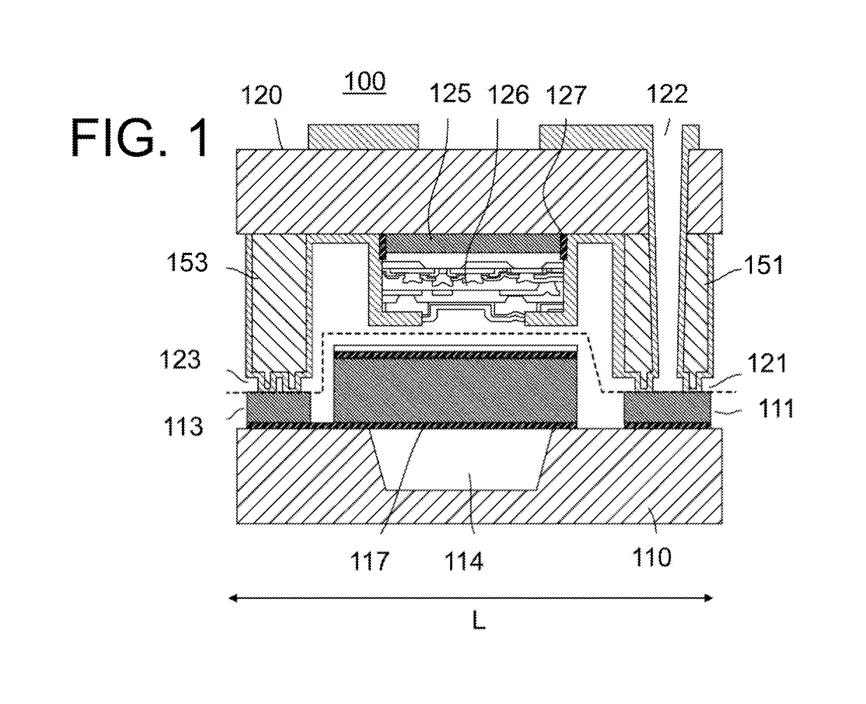

FIG. 1 shows a cross-sectional view of a packaged device 100 in accordance with a representative embodiment.

Packaged device 100 comprises a base substrate 110 and a cap substrate 120. Base substrate 110 has on a first surface (upper surface as shown in FIG. 1) thereof: a first bonding pad 111; a second bonding pad 113; and a recessed region 114. Base substrate 110 further comprises a peripheral pad (not shown in FIG. 1) on a first surface. Also, in some embodiments base substrate 110 may comprise additional bonding pads (not shown), which are substantially the same as first and second bonding pads 111 and 113.

Cap substrate 120 has on a first surface (lower surface as shown in FIG. 1) thereof: bonding pad seal 121 provided on a standoff 151 and an electrically conductive (e.g., metal) layer(s) disposed thereon, having a corresponding through hole 122 formed in cap substrate 120; a drop down contact post 123 provided with a standoff 153 and an electrically conductive (e.g., metal) layer(s) disposed thereon; a low-resistivity material layer (e.g., epitaxial layer) region 125; and electronic circuitry 126 formed on low-resistivity material layer (e.g., epitaxial layer) region 125.

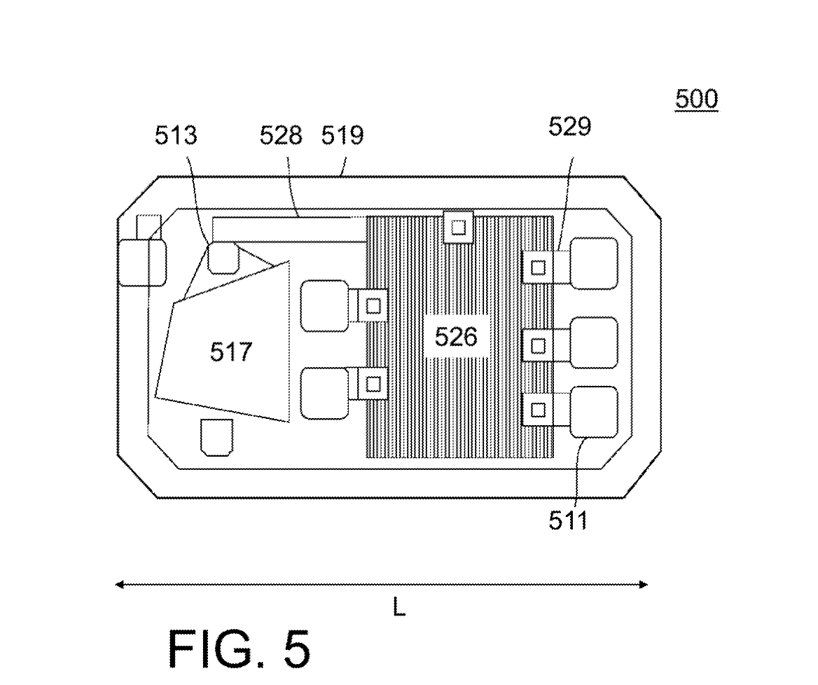

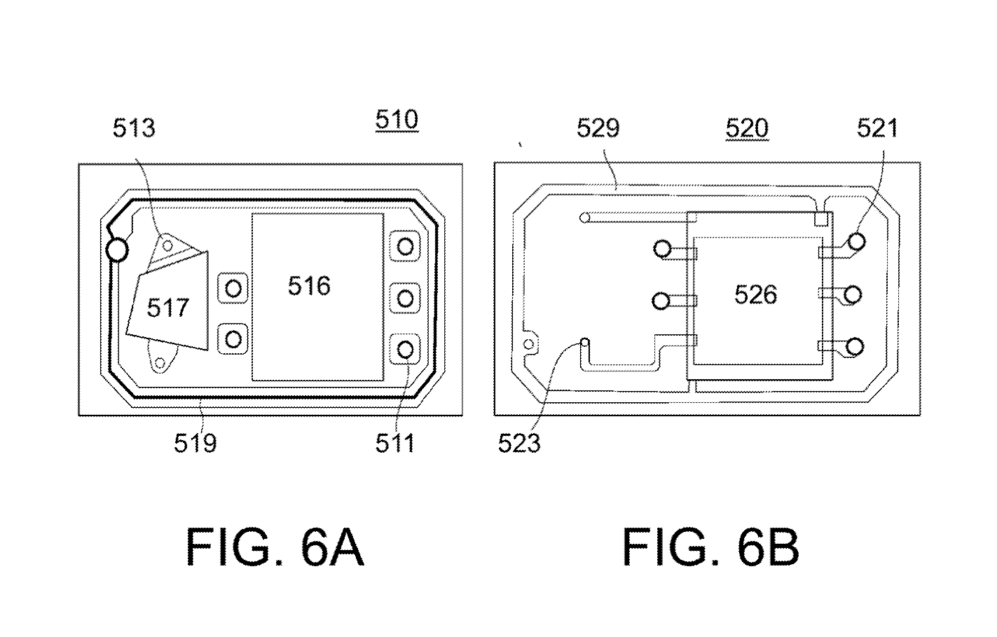

Cap substrate 120 further comprises on the first surface thereof, a peripheral pad seal not shown in FIG. 1, but examples of which are illustrated in FIGS. 5 and 6B. Also, in some embodiments cap substrate 120 may include additional bonding pad seals 121, including corresponding through holes 122, and/or additional drop down contact posts 123. In some embodiments, one or more of the through holes 122 in cap substrate 120 are plated or otherwise filled with an electrically conductive material (e.g., metal) to provide an electrical connection between the corresponding bonding pad seal 121 and a second surface (upper surface as shown in FIG. 1) thereof.

Packaged device 100 further comprises an acoustic resonator 117 disposed on base substrate 110 above recessed region 114. In some embodiments, acoustic resonator 117 is electrically connected to electronic circuitry 126, for example by second bonding pad 113 and the conductive (e.g., metal) layer(s) of the drop down contact post 123. In some embodiments, acoustic resonator 117 comprises a bulk acoustic wave (BAW) resonator, such as a film bulk acoustic resonator (FBAR) or a solidly mounted resonator (SMR).

In accordance with representative embodiments the FBAR or the SMR device may be provided in an arrangement with a semiconductor substrate (e.g., cap substrate 120) comprising various electrical and electronic components, devices and circuits. Such an arrangement comprising an FBAR (or SMR) and such electrical and electronic components may be referred to as an FMOS device. To this end, the term “FMOS” refers generally to an arrangement in which one substrate (e.g., base substrate 110) comprises a BAW resonator, such as an FBAR, and another substrate (cap substrate 120) comprises the passive and active electrical devices, and circuits.

In some representative embodiments, the cap substrate 120 comprises a semiconductor material (e.g., silicon) that is compatible with complimentary metal-oxide-semiconductor (CMOS) devices and well as bipolar devices, which are fabricated therein/thereover. This general arrangement of the BAW resonator (e.g., FBAR) on the base substrate 110 and the CMOS/bipolar devices on the cap substrate 120 lends itself to the acronym FMOS. However, it is to be noted that the cap substrate 120 is not limited to materials normally reserved for MOS and bipolar technologies. Rather, the cap substrate 120 may comprise silicon-on-insulator (SOI) substrates; and III-V semiconductor materials (e.g., binary and ternary materials) comprising, for example, heterojunction bipolar transistor (HBT) circuits, or high electron mobility transistor (HEMT), or pseudomorphic HEMT (pHEMT) circuits.

In some representative embodiments, cap substrate 120 comprises an electronically non-conductive material or a high-resistivity semiconductor material, such as single crystal silicon. In alternative embodiments, cap substrate 120 may comprise other high-resistivity materials, for example SOI, and low-resistivity material layer region 125 may be formed by controlled doping of the SOI substrate.

In some embodiments, base substrate 110 and cap substrate 120 comprise materials that have the substantially the same or approximately the same coefficient of thermal expansion (CTE) as each other, to avoid thermal expansion mismatch problems. In some embodiments, base substrate 110 and cap substrate 120 are made of the same semiconductor material.

Standoffs 151, 153 are provided on the first surface of cap substrate 120. The standoffs 151,153 may comprise a material different than the semiconductor material of cap substrate 120. In some embodiments, standoffs 151 and 153 are formed of an electrically insulating material which may be covered with one or more electrically conductive (e.g., metal) layers. In other embodiments, standoffs 151 and 153 are formed of an electrically conductive material, for example copper or gold. By employing standoffs 151 and 153, a distance between the first surface of cap substrate 120 and base substrate 110 can be increased. Accordingly, in packaged device 100, electronic circuitry 126 is disposed directly opposite and confronting acoustic resonator 117. Thus packaged device 100 may have a reduced length or lateral dimension (“L” dimension in FIGS. 1, 4 and 5) compared to packaged FMOS devices 400 and 500, all other factors being equal.

In some embodiments one or more portions of low-resistivity material layer (e.g., epitaxial layer) is removed between bonding pad seals 121, drop down contact posts 123, and the peripheral pad seal, so as to eliminate a current path through the epitaxial material between any two of the bonding pad seals 121, drop down contact posts 123, and the peripheral pad seal. Furthermore, in some embodiments one or more portions of low-resistivity material layer (e.g., epitaxial layer) material is removed so as to eliminate a current path between low-resistivity material layer (e.g., epitaxial layer) region 125 and the conductive layer(s) of some or all of the bonding pad seals 121, and/or drop down contact posts 123, and/or the peripheral pad seal.

In a representative embodiment of packaged device 100 shown in FIG. 1, the low-resistivity material layer (e.g., epitaxial layer) is eliminated except for: (1) low-resistivity material layer (e.g., epitaxial layer) region 125, which is isolated from some or all of the bonding pad seals 121, and/or drop down contact posts 123, and/or the peripheral pad seal; and (2) one or more low-resistivity material layer (e.g., epitaxial layer) portions remaining in the treads of one or more of the bonding pad seal(s) 121, drop down contact post(s) 123 and the peripheral pad seal. Furthermore, cap substrate 120 of packaged device 100 comprises an electrically insulating layer 127, which electrically isolates low-resistivity material layer (e.g., epitaxial layer) region 125 from one or more electrically conductive (e.g., metal) layers or traces in contact with bonding pad seal(s) 121 and drop down contact post(s) 123. In some embodiments, electrically insulating layer 127 partially or totally encompasses or surrounds low-resistivity material layer (e.g., epitaxial layer) region 125.

In a variation of packaged device 100 (particularly where standoff 151 is formed of a substantially solid electrically conductive material, for example copper or gold), through hole 122 may not extend through standoff 151 down to first bonding pad 111, in which case standoff 151 may be considered to be a pad on the bottom surface of cap substrate 120.

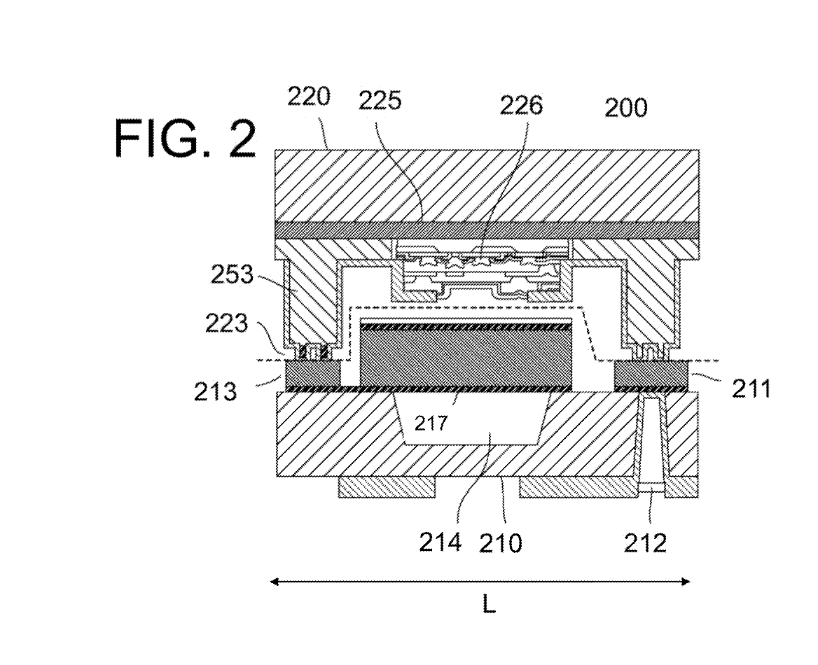

FIG. 2 shows another representative embodiment of a packaged device 200. Aspects and details of the various components of packaged device 100 are common to packaged device 200, and are not repeated to avoid obscuring the description of the presently described representative embodiments.

Packaged device 200 comprises a base substrate 210 and a cap substrate 220. Base substrate 210 has on a first surface (upper surface as shown in FIG. 2) thereof: a first bonding pad 211, having a corresponding through hole 212 formed in base substrate 210; a second bonding pad 213; and a recessed region 214. Base substrate 210 further comprises on the first surface thereof a peripheral pad not shown in FIG. 2, but examples of which are illustrated in FIGS. 5 and 6A. Also, in some embodiments base substrate 210 may include additional first bonding pads 211, including corresponding through holes 212, and second bonding pads 213.

Cap substrate 220 comprises on a first surface (lower surface as shown in FIG. 2) thereof: drop down contact post 223 provided with a standoff 253 and one or more conductive (e.g., metal) layer(s) disposed thereon; a low-resistivity material layer (e.g., epitaxial layer) region 225; and electronic circuitry 226 formed on low-resistivity material layer (e.g., epitaxial layer) region 225. Cap substrate 220 further comprises on the first surface thereof a peripheral pad seal not shown in FIG. 2, but examples of which are illustrated in FIGS. 5 and 6B. Also, in some embodiments cap substrate 220 may include additional drop down contact posts 223.

In some representative embodiments, one or more of the through holes 212 in base substrate are plated or otherwise filled with a conductive material (e.g., metal) to provide an electrical connection between the corresponding bonding pad 211 and a second surface (bottom surface as shown in FIG. 2) thereof.

Packaged device 200 further comprises a BAW resonator 217 disposed on base substrate 210 above recessed region 214. In some embodiments, BAW resonator 217 is electrically connected to electronic circuitry 226 by means of drop down contact post(s) 223. In some embodiments, BAW resonator 217 comprises a film bulk acoustic resonator (FBAR). In other embodiments, BAW resonator 217 comprises a solidly mounted resonator (SMR).

Like packaged device 100, the FBAR or the SMR of packaged device may be provided in an arrangement with a semiconductor substrate (e.g., cap substrate 220) comprising various electrical and electronic components, devices and circuits. As noted above, such an arrangement comprising an FBAR (or SMR) and such electrical and electronic components may be referred to as an FMOS device.

In some representative embodiments, the cap substrate 220 comprises a semiconductor material (e.g., silicon) that is compatible with complimentary metal-oxide-semiconductor (CMOS) devices and well as bipolar devices, which are fabricated therein/thereover. This general arrangement of the BAW resonator (e.g., FBAR) on the base substrate 210 and the CMOS/bipolar devices on the cap substrate 220 lends itself to the acronym FMOS. However, it is to be noted that the cap substrate 220 is not limited to materials normally reserved for MOS and bipolar technologies. Rather, the cap substrate 220 may comprise silicon-on-insulator (SOI) substrates; and III-V semiconductor materials (e.g., binary and ternary materials) comprising, for example, heterojunction bipolar transistor (HBT) circuits, or high electron mobility transistor (HEMT), or pseudomorphic HEMT (pHEMT) circuits.

In some representative embodiments, cap substrate 220 comprises an electronically non-conductive material or a high-resistivity semiconductor material, such as single crystal silicon. In alternative embodiments, cap substrate 220 may comprise other high-resistivity materials, for example SOI, and low-resistivity material layer region 125 may be formed by controlled doping of the SOI substrate.

In some embodiments, base substrate 210 and cap substrate 220 comprise materials that have the substantially the same or approximately the same coefficient of thermal expansion (CTE) as each other, to avoid thermal expansion mismatch problems. In some embodiments, base substrate 210 and cap substrate 220 are made of the same semiconductor material.

In a beneficial feature, low-resistivity material layer (e.g., epitaxial layer) region 225 on cap substrate 220 is electrically isolated from the conductive (e.g., metal) layer(s) of some or all of the drop down contact posts 223, and/or the peripheral pad seal.

Provided on the first surface of cap substrate 220 are standoff(s) 253 formed of a material different than the semiconductor material of cap substrate 220. In some embodiments, standoff(s) 253 are formed of an electrically insulating material. By employing standoff(s) 253, a distance between the first surface of cap substrate 220 and base substrate 210 can be increased. Accordingly, in packaged device 200, electronic circuitry 226 is disposed directly opposite and confronting BAW resonator 217. Thus packaged device 200 may have a reduced length or lateral dimension (“L” dimension in FIGS. 2, 4 and 5) compared to packaged FMOS devices 400 and 500, all other factors being equal.

In packaged device 200, since through holes 212 are provided in base substrate 210 instead of in the cap substrate as in devices 100, 400 and 500, the epitaxial layer on the first surface of cap substrate 220 can be left intact, and electrical isolation can be provided by standoff(s) 253.

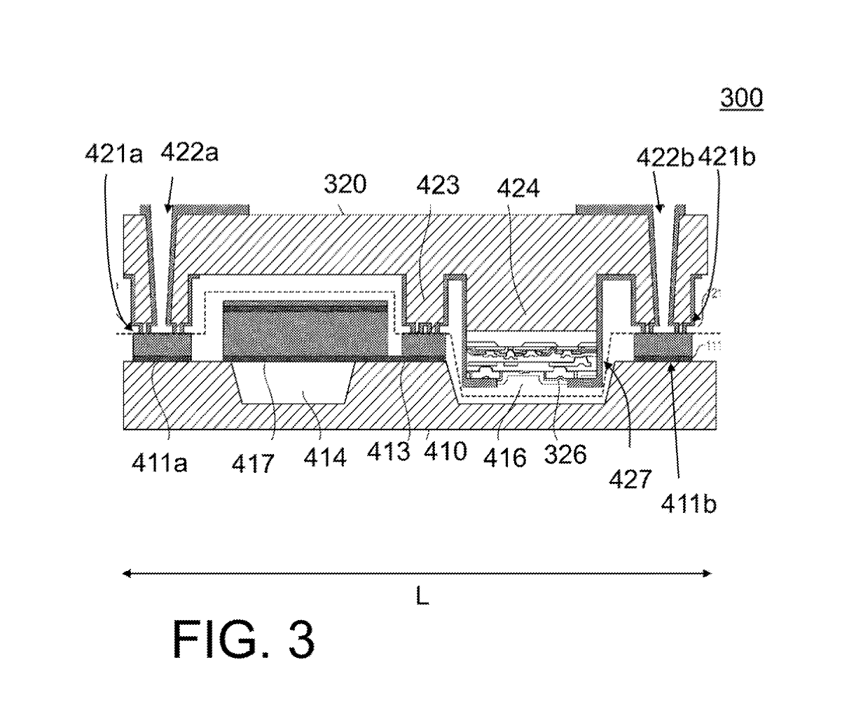

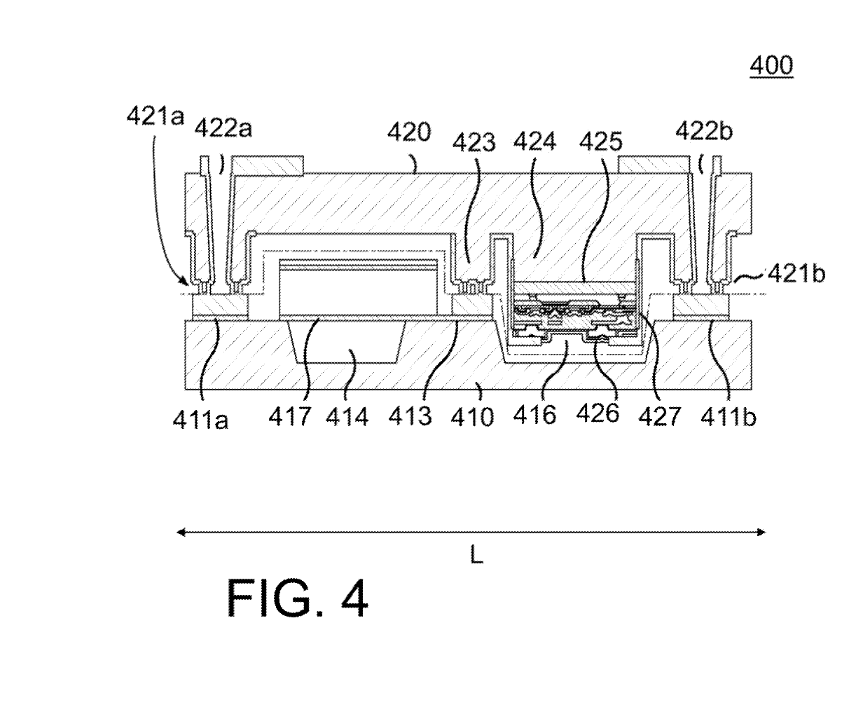

FIG. 3 shows yet another representative embodiment of a packaged device 300. Packaged device 300 is substantially the same as packaged FMOS device 400 illustrated in FIG. 4, except that in packaged device 300, electronic circuitry 326 comprises CMOS devices, and cap substrate 320 does not have any low-resistivity material layer such as an epitaxial layer. It should be noted that embodiments similar to those shown in FIGS. 1 and 2 could also be produced with CMOS devices and no low-resistivity material layer or epitaxial layer as with the packaged device 300 shown in FIG. 3.

FIG. 4 shows a cross-sectional view of a portion of one representative embodiment of a packaged “FMOS” device 400. Packaged FMOS device 400 comprises a base substrate 410 and a lid substrate 420.

Base substrate 410 has on a first surface (top surface as shown in FIG. 4) thereof: first bonding pads 411a and 411b; a second bonding pad 413; a first recessed region 414; and a second recessed region 416. Base substrate 410 further includes on the first surface thereof a peripheral pad not shown in FIG. 4, but examples of which are illustrated in FIGS. 5 and 6A. Beneficially, first bonding pads 411a and 411b, second bonding pad 413, and the peripheral pad are formed of an electrically conductive (e.g., metal) material. Also, in some embodiments base substrate 410 may include additional first and second bonding pads 411 and 413.

Lid substrate 420 has on a first surface (bottom surface as shown in FIG. 4) thereof: bonding pad seals 421a and 421b, each having a corresponding through hole 422a and 422b formed in lid substrate 420; a drop down contact post 423; a pedestal 424; a low-resistivity material layer region 425; and electronic circuitry 426 formed on low-resistivity material layer region 425. Lid substrate 420 further includes on the first surface thereof a peripheral pad seal not shown in FIG. 4, but examples of which are illustrated in FIGS. 5 and 6B. Beneficially, bonding pad seals 421a and 421b and drop down contact post 423 each have an electrically conductive (e.g., a metal such as gold) layer thereon for making contact with the corresponding first and second bonding pads 411 and 413. Also, in some embodiments lid substrate 420 may include additional bonding pad seals 421 and/or additional drop down contact posts 423. In some embodiments, one or more of through holes 422 in lid substrate 420 are plated or otherwise filled with a conductive material (e.g., metal) to provide an electrical connection between the metal layer of a corresponding bonding pad seal 421 and a second surface (top surface as shown in FIG. 4) of lid substrate 420, for example a pad on the second surface of lid substrate 420. As shown in FIG. 4, in some embodiments, bonding pad seals 421 and/or drop down contact posts 423 include treads or gaskets that are covered with the electrically conductive material.

Packaged FMOS device 400 further comprises an acoustic resonator 417 disposed on base substrate 410 above first recessed region 414. In some embodiments, acoustic resonator 417 is electrically connected to electronic circuitry 426, for example by means of second bonding pad 413 and the conductive (e.g., metal) layer on drop down contact post 423. In some embodiments, acoustic resonator 417 comprises a film bulk acoustic resonator (FBAR). In other embodiments, a solidly mounted resonator (SMR) may be employed. In some embodiments, electronic circuitry 426 includes one or more transistors or other active devices of an oscillator circuit that operates with acoustic resonator 417 to form an oscillator

In accordance with representative embodiments the FBAR or the SMR device may be provided in an arrangement with a semiconductor substrate (e.g., lid substrate 420) comprising various electrical and electronic components, devices and circuits.

In some representative embodiments, the lid substrate 420 comprises a semiconductor material (e.g., silicon) that is compatible with complimentary metal-oxide-semiconductor (CMOS) devices and well as bipolar devices, which are fabricated therein/thereover. This general arrangement of the BAW resonator (e.g., FBAR) on the base substrate 410 and the CMOS/bipolar devices on the lid substrate 420 lends itself to the acronym FMOS. However, it is to be noted that the lid substrate 420 is not limited to materials normally reserved for MOS and bipolar technologies. Rather, the lid substrate 420 may comprise silicon-on-insulator (SOI) substrates; and III-V semiconductor materials (e.g., binary and ternary materials) comprising, for example, heterojunction bipolar transistor (HBT) circuits, or high electron mobility transistor (HEMT), or pseudomorphic HEMT (pHEMT) circuits.

In some representative embodiments, lid substrate 420 comprises an electronically non-conductive material or a high-resistivity semiconductor material, such as single crystal silicon. In alternative embodiments, lid substrate 420 may comprise other high-resistivity materials, for example SOI, and low-resistivity material layer region 425 may be formed by controlled doping of the SOI substrate.

In some embodiments, base substrate 410 and lid substrate 420 comprise materials that have the substantially the same or approximately the same coefficient of thermal expansion (CTE) as each other, to avoid thermal expansion mismatch problems. In some embodiments, base substrate 410 and lid substrate 420 are made of the same semiconductor material.

As noted above, in some embodiments lid substrate 420 is a semiconductor substrate. In general, such a semiconductor substrate on which electronic circuitry 426 is to be fabricated will have a low-resistivity material layer disposed on all or substantially all of a surface thereof for the formation of the semiconductor or active devices of electronic circuitry 426. In particular, such a low-resistivity material layer comprises a material that has a substantially lower resistivity than the high-resistivity semiconductor material of lid substrate 420. As used herein, “substantially lower resistivity” means about one order of magnitude lower resistivity, or more than one order of magnitude lower resistivity, for example as measured in terms of Ω-cm. For example, in some embodiments, the high-resistivity semiconductor material of lid substrate 420 has a resistivity of more than 1000 Ω-cm, while the low-resistivity material of a low-resistivity material layer has a resistivity of less than 100Ω including in some embodiments a resistivity in a range of 10 Ω-cm. Accordingly, if left intact on lid substrate 420, such a low-resistivity material layer may provide a low electrical impedance path or electrical short between the conductive (e.g., metal) layer(s) of bonding pad seals 421 and/or drop down contact post(s) 423. This can degrade the performance of packaged FMOS device 400, and in some cases may render packaged FMOS device 400 inoperable.

Accordingly, in some embodiments one or more portions of the low-resistivity material layer is removed between bonding pad seals 421, drop down contact posts 423, and the peripheral pad seal so as to eliminate a current path through the low-resistivity material layer between any of the bonding pad seals 421, drop down contact posts 423, and the peripheral pad seal. Furthermore, in some embodiments one or more portions of the low-resistivity material layer are removed so as to eliminate a current path between low-resistivity material layer region 425 and the conductive layer(s) of some or all of the bonding pad seals 421, and/or drop down contact posts 423, and/or the peripheral pad seal.

In a representative embodiment of packaged FMOS device 400 shown in FIG. 4, the low-resistivity material layer (e.g., epitaxial layer) is eliminated except for: (1) low-resistivity material layer (e.g., epitaxial layer) region 425, which is isolated from some or all of the bonding pad seals 421, and/or drop down contact posts 423, and/or the peripheral pad seal; and (2) one or more low-resistivity material layer (e.g., epitaxial layer) portions remaining in the treads of one or more of the bonding pad seal(s) 421, drop down contact post(s) 423, and the peripheral pad seal. Furthermore, lid substrate 420 of packaged FMOS device 400 includes an electrically insulating material 427 (e.g., an oxide such as silicon oxide) electrically isolating low-resistivity material layer (e.g., epitaxial layer) region 425 from one or more electrically conductive (e.g., metal) layers or traces in contact with bonding pad seal(s) 421 and drop down contact post(s) 423. In some embodiments, electrically insulating material 427 partially or totally encompasses or surrounds low-resistivity material layer (e.g., epitaxial layer) region 425.

In some representative embodiments, lid substrate 420 may have a low-resistivity material layer (e.g., epitaxial layer) formed entirely on the first surface thereof, and the low-resistivity material layer (e.g., epitaxial layer)—except for low-resistivity material layer (e.g., epitaxial layer) region 425 and the low-resistivity material layer (e.g., epitaxial layer) portions remaining in the treads—may be removed after formation of electronic circuitry 426. In other embodiments, the low-resistivity material layer (e.g., epitaxial layer)—except for low-resistivity material layer (e.g., epitaxial layer) region 425 and the low-resistivity material layer (e.g., epitaxial layer) portions remaining in the treads—may be removed before formation of electronic circuitry 426.

In other representative embodiments, the low-resistivity material layer (e.g., epitaxial layer) is only removed in areas surrounding each of the bonding pad seals 421, and/or drop down contact posts 423, and/or the peripheral pad seal so as to electrically isolate the bonding pad seals 421, and/or drop down contact posts 423, and/or the peripheral pad seal from each other and/or from electronic circuitry 426.

FIG. 5 shows a top cutaway view of another representative embodiment of a packaged FMOS device 500. Packaged FMOS device 500 comprises a base substrate 510 and a lid substrate 520, which are better seen in FIGS. 6A and 6B. FIG. 5 illustrates an electrically conductive trace or connection 528 between electronic circuitry 526 and a BAW resonator 517 of packaged FMOS device 500 via second bonding pad 513 and drop down contact post 523 (see FIG. 6B), and an electrically conductive trace or connection 528 between electronic circuitry 526 of packaged FMOS device 500 and first bonding pad 511 via bonding pad seal 521. FIG. 5 also shows that BAW resonator 517 is laterally offset with respect to electronic circuitry 526 in packaged FMOS device 500.

In particular, FIG. 6A shows base substrate 510, and FIG. 6B shows lid substrate 520. FIG. 6A illustrates first bonding pad 511, second bonding pad 513, peripheral pad 519, a second recessed region 516 that is disposed beneath electronic circuitry 526 when base substrate 510 is bonded to lid substrate 520 to form packaged FMOS device 500. FIG. 6B shows peripheral pad seal 529, bonding pad seal 521, and drop down contact post 523.

Packaged FMOS device 500) may include features described above with respect to packaged FMOS device 400, including electrical isolation of an epitaxial layer region on lid substrate 520 from bonding pad seal 521, drop down contact post 523 and peripheral pad seal 529.

In some embodiments, base substrates 410/510, and lid substrates 420/520, are configured to be parametrically tested individually prior to assembly.

An example process of assembling packaged FMOS devices 400 and 500 will now be described.

In the representative embodiment, bonding pad treads or gaskets of bonding pad seal(s) 521 match the perimeters of the first bonding pad(s) 511 on the base substrate 510, drop down contact post treads or gaskets of drop down contact post(s) 523 match the perimeters of the second bonding pad(s) 513 on the base substrate 510, and peripheral pad treads or gaskets of the peripheral pad seal 529 match the peripheral pad 519 on the base substrate 510. Wells are located inside the perimeters of the bond pad gaskets and are formed to a predetermined depth in the lid substrate 520. The lid substrate 520 is then placed over the base substrate 510 so as to bond (e.g., a cold weld bond) the peripheral pad seal 529 to the peripheral pad 519, and to like wise bond the bonding pad seal(s) 521 and the drop down contact post(s) 523 to corresponding of the first and second bonding pads 511, 513 and form a sealed volume between the bonding pad seals 521 and the peripheral pad seal 529.

The lid substrate 520 is thinned to form a so-called “microcap”. Essentially, the microcap is thinned below a predetermined depth until the wells become through holes that provide access for making an electrical connection to the bonding pads inside the package, but outside the sealed volume, for external conductors, which may include conductive wires provided inside the though holes and/or a conductive (e.g., metal) layer plated or deposited in the through holes. This arrangement assures a highly reliable seal for devices (e.g., electronic circuitry and acoustic resonator) inside the package, while allowing electrical connections without passing through a seal. Further, this process permits the substrates to be made thin because it forms the microcap in situ and avoids the handling of the fragile microcap during assembly.

A description of additional details regarding embodiments of methods of assembling a lid substrate to a base substrate is provided in U.S. Pat. No. 6,429,511, the disclosure of which is hereby incorporated herein by reference as if set forth herein.

When the base substrate 510 and lid substrate 520 are bonded together as described above a sealed volume is formed between the lid substrate 520 and the base substrate 510. In that case, the BAW resonator 517, the low-resistivity material layer (e.g., epitaxial layer) region 525, the electronic circuitry 526, the second bonding pad(s) 513, and the drop down contact post(s) 523 are disposed within the sealed volume.

In some embodiments, base substrates 410/510, and lid substrates 420/520, are individually parametrically tested prior to their being bonded together. The packaging arrangement illustrated above with respect to packaged FMOS devices 400 and 500 may be employed for a variety of electronic devices.

In some embodiments, packaged FMOS devices 400 and/or 500 may comprise an oscillator, mixer and other possible electronic circuits. In that case, electronic circuitry 426/526 may comprise oscillator circuitry that includes one or more transistors or other active devices of the oscillator. Beneficially, the packaging arrangement of packaged FMOS devices 400 and 500) may provide certain benefits for such an oscillator, including a small size, and tight coupling between the BAW resonator 517 and the active circuitry of the oscillator, which can reduce noise and losses and therefore improve performance of the oscillator.

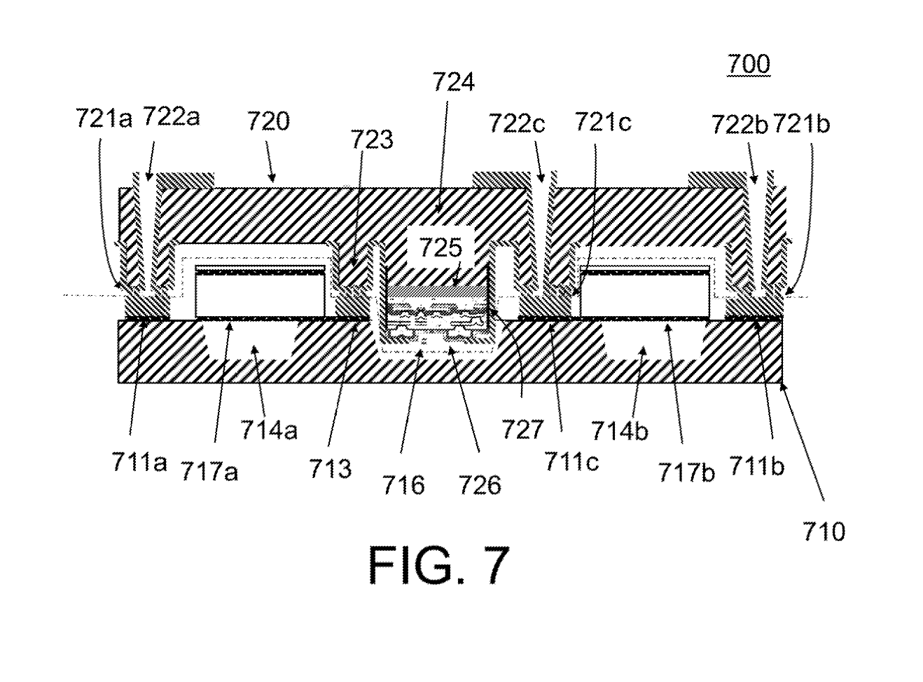

FIG. 7 shows a representative embodiment of a packaged FMOS device 700 with two FBAR oscillators. While two FBAR oscillators are shown by way of example in packaged FMOS device 700, it should be understood that more than two FBAR oscillators may be employed. Packaged FMOS device 700 may be employed in a detector. One or more of the FBAR oscillators of FIG. 7 may be coupled with one or more transducers (not shown in FIG. 7). For example, packaged FMOS device 700 with two FBAR oscillators may be employed in a combined accelerometer and rotation detector, as disclosed in U.S. patent application Ser. No. 13/162,883 filed on Jun. 17, 2011 in the name of Richard Ruby, the entirety of which are hereby incorporated herein by references as if fully set forth herein. In other words, it should be understood that one or more of the FBAR oscillators of FIG. 7 may be employed in a detector. Further, the first acoustic resonator may form a portion of a reference oscillator, while the second acoustic resonator may form a portion of a second oscillator configured for coupling with a detector. Differential circuitry may be coupled with the reference oscillator and the second oscillator. The differential circuitry may be embodied as at least a portion of electronic circuitry 726 shown in FIG. 7.

Packaged FMOS device 700 comprises a base substrate 710 and a lid substrate 720.

Base substrate 710 has on a first surface (top surface as shown in FIG. 7) thereof: first bonding pads 711a, 711b and 711c; a second bonding pad 713; first recessed regions 714a and 714b; and a second recessed region 716. Base substrate 710 further includes on the first surface thereof a peripheral pad not shown in FIG. 7, but examples of which are illustrated in FIGS. 5 and 6A above. Beneficially, first bonding pads 711 and second bonding pad(s) 713, and the peripheral pad are formed of an electrically conductive (e.g., metal) material. Also, in some embodiments base substrate 710 may include additional first and second bonding pads 711 and 713.

Lid substrate 720 has on a first surface (bottom surface as shown in FIG. 7) thereof: bonding pad seals 721a, 721b and 721c, each having a corresponding through hole 722a, 722b and 722c formed in lid substrate 720; a drop down contact post 723; a pedestal 724; a low-resistivity material layer region 725; and electronic circuitry 726 formed on low-resistivity material layer region 725. Lid substrate 720 further includes on the first surface thereof a peripheral pad seal not shown in FIG. 7, but examples of which are illustrated in FIGS. 5 and 6B. Beneficially, bonding pad seals 721a, 721b and 721c and drop down contact post 723 each have an electrically conductive (e.g., a metal such as gold) layer thereon for making contact with the corresponding first and second bonding pads 711 and 713. Also, in some embodiments lid substrate 720 may include additional bonding pad seals 721 and/or additional drop down contact posts 723. In some embodiments, one or more of through holes 722 in lid substrate 720 are plated or otherwise filled with a conductive material (e.g., metal) to provide an electrical connection between the metal layer of a corresponding bonding pad seal 721 and a second surface (top surface as shown in FIG. 7) of lid substrate 720, for example a pad on the second surface of lid substrate 720. As shown in FIG. 7, in some embodiments, bonding pad seals 721 and/or drop down contact posts 723 include treads or gaskets that are covered with the electrically conductive material.

Packaged FMOS device 700 further comprises first and second BAW resonators 717a and 717b disposed on base substrate 710 above corresponding first recessed regions 714a and 714b. In some embodiments, first and second BAW resonators 717a and 717b are each electrically connected to electronic circuitry 726, for example by means of first and/or second bonding pads 711, 713 and the conductive (e.g., metal) layer on bonding pad seal(s) 721 and/or drop down contact post 723. In some embodiments, each of the first and second BAW resonators 717a and 717b comprises a film bulk acoustic resonator (FBAR). In other embodiments, a solidly mounted resonator (SMR) may be employed. In some embodiments, electronic circuitry 726 includes one or more transistors or other active devices for two oscillators that operate respectively with first and second BAW resonators 717a and 717b. In some embodiments, electronic circuitry 726 may include one or more other elements, including for example a first mixer, a diplexer, a second mixer and/or filter.

In some embodiments, base substrate 710 and/or lid substrate 720 comprise a semiconductor substrate. In some embodiments, lid substrate 720 can be made of an electronically non-conductive material or a high-resistivity semiconductor material, such as single crystal silicon. Also, in some embodiments when lid substrate 720 is a semiconductor substrate, low-resistivity material layer region 725 comprises an epitaxial layer formed on the semiconductor substrate. In alternative embodiments, lid substrate 720 may comprise other high-resistivity materials, for example a silicon-on-insulator (SOI) substrate, and low-resistivity material layer region 725 may be formed by controlled doping of the SOI substrate.

In some embodiments, base substrate 710 and lid substrate 720 are made of materials that have the same or approximately the same coefficient of thermal expansion (CTE) as each other to avoid thermal expansion mismatch problems. In some embodiments base substrate 710 and lid substrate 720 are made of the same semiconductor material as each other.

As noted above, in some embodiments lid substrate 720 is a semiconductor substrate. In general, such a semiconductor substrate on which electronic circuitry 726 is to be fabricated will have a low-resistivity material layer disposed on all or substantially all of a surface thereof for the formation of the semiconductor or active devices of electronic circuitry 726. In particular, such a low-resistivity material layer comprises a material that has a substantially lower resistivity than the high-resistivity semiconductor material of lid substrate 720. As used herein, “substantially lower resistivity” means about one order of magnitude lower resistivity, or more than one order of magnitude lower resistivity, for example as measured in terms of Ω-cm. For example, in some embodiments, the high-resistivity semiconductor material of lid substrate 720 has a resistivity of more than 1000 Ω-cm, while the low-resistivity material of a low-resistivity material layer has a resistivity of less than 100 Ω-cm, including in some embodiments a resistivity in a range of 10 Ω-cm. Accordingly, if left intact on lid substrate 720, such a low-resistivity material layer may provide a low impedance path or electrical short between the conductive (e.g., metal) layer(s) of bonding pad seals 721 and/or drop down contact post(s) 723. This can degrade the performance of packaged FMOS device 700, and in some cases may render packaged FMOS device 700 inoperable.

Accordingly, in some embodiments one or more portions of the low-resistivity material layer is removed between bonding pad seals 721, drop down contact posts 723, and the peripheral pad seal so as to eliminate a current path through the low-resistivity material layer between any of the bonding pad seals 721, drop down contact posts 723, and the peripheral pad seal. Furthermore, in some embodiments one or more portions of the low-resistivity material layer are removed so as to eliminate a current path between low-resistivity material layer region 725 and the conductive layer(s) of some or all of the bonding pad seals 721, and/or drop down contact posts 723, and/or the peripheral pad seal.

In a particular embodiment of packaged FMOS device 700 shown in FIG. 7, the low-resistivity material layer (e.g., epitaxial layer) is eliminated except for: (1) low-resistivity material layer (e.g., epitaxial layer) region 725, which is isolated from some or all of the bonding pad seals 721, and/or drop down contact posts 723, and/or the peripheral pad seal; and (2) one or more low-resistivity material layer (e.g., epitaxial layer) portions remaining in the treads of one or more of the bonding pad seal(s) 721, drop down contact post(s) 723, and the peripheral pad seal. Furthermore, lid substrate 720 of packaged FMOS device 700 includes an electrically insulating material 727 (e.g., an oxide such as silicon oxide) electrically isolating low-resistivity material layer (e.g., epitaxial layer) region 725 from one or more electrically conductive (e.g., metal) layers or traces in contact with bonding pad seal(s) 721 and drop down contact post(s) 723. In some embodiments, electrically insulating material 727 partially or totally encompasses or surrounds low-resistivity material layer (e.g., epitaxial layer) region 725.

In some embodiments, lid substrate 720 may have a low-resistivity material layer (e.g., epitaxial layer) formed entirely on the first surface thereof, and the low-resistivity material layer (e.g., epitaxial layer)—except for low-resistivity material layer (e.g., epitaxial layer) region 725 and the low-resistivity material layer (e.g., epitaxial layer) portions remaining in the treads—may be removed after formation of electronic circuitry 726. In other embodiments, the low-resistivity material layer (e.g., epitaxial layer)—except for low-resistivity material layer (e.g., epitaxial layer) region 725 and the low-resistivity material layer (e.g., epitaxial layer) portions remaining in the treads—may be removed before formation of electronic circuitry 726.

In other embodiments, the low-resistivity material layer (e.g., epitaxial layer) is only removed in areas surrounding each of the bonding pad seals 721, and/or drop down contact posts 723, and/or the peripheral pad seal so as to electrically isolate the bonding pad seals 721, and/or drop down contact posts 723, and/or the peripheral pad seal from each other and/or from electronic circuitry 726.

For the packaged FMOS device 700, the lid substrate 720 may have drop down contact post 723 bonded to second bonding pad 713 and providing electrical connection between first and second BAW resonator 717a and the electronic circuitry 726. Low resistivity material layer region 725 may be electrically isolated from the drop down contact post 723. First and second BAW resonators 717a, 717b may be electrically connected with one another.

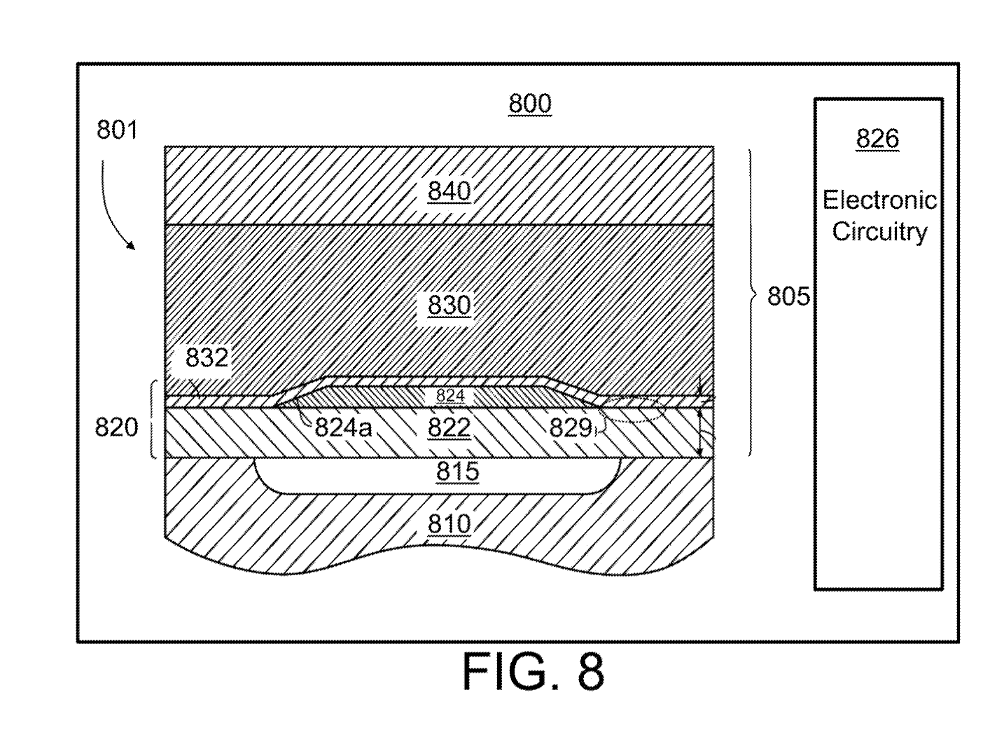

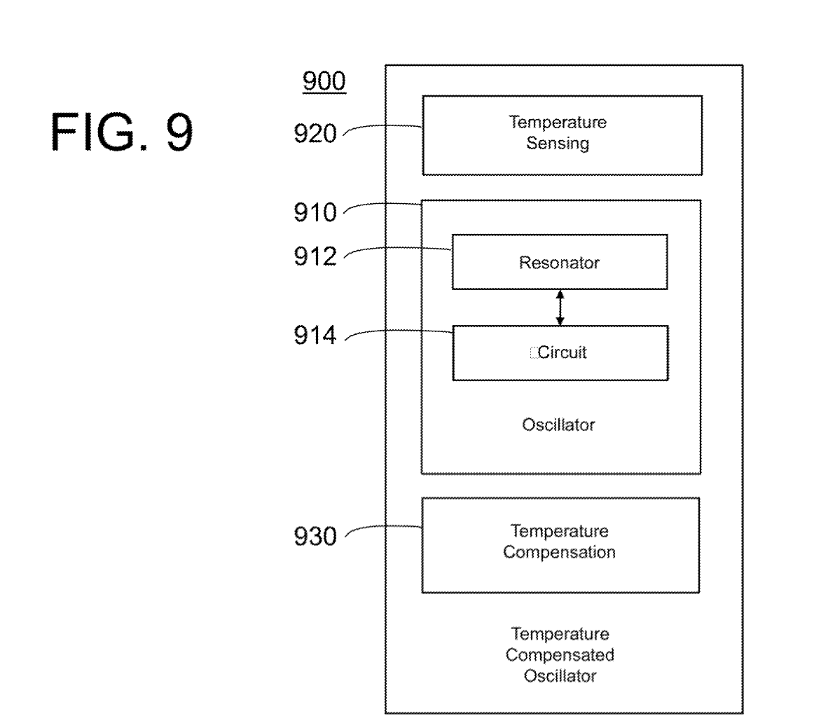

FIGS. 8 and 9 show representative embodiments of a temperature compensated oscillator of the packaged device. FIG. 8 shows a partial block diagram of a packaged device 800 comprising a temperature compensated oscillator. The temperature compensated oscillator may comprise a temperature compensated BAW resonator 801 coupled with electronic circuitry 826. The temperature compensated BAW resonator 801 may be a temperature compensated FBAR. Further, in a beneficial arrangement, a packaged device may provide one or more temperature compensated oscillators using methods and devices disclosed in above-referenced U.S. Pat. No. 8,232,845, and further disclosed in above-referenced U.S. patent application Ser. No. 13/162,883 filed on Jun. 17, 2011. Accordingly, FIG. 9 shows a functional block diagram of another representative embodiment of a temperature compensated oscillator.

FIG. 8 shows a cross-sectional view of a temperature compensated BAW resonator 801, which includes an electrode having a buried temperature compensation layer 824, according to a representative embodiment. As particularly shown in FIG. 8, a temperature compensated oscillator may comprise the temperature compensated BAW resonator 801 coupled with electronic circuitry 826. In a representative embodiment, the temperature compensated BAW resonator 801 may be a temperature compensated FBAR. Further, a packaged device may provide one or more temperature compensated BAW resonator 801 using methods and devices disclosed in above-referenced U.S. Pat. No. 8,232,845, and U.S. patent application Ser. No. 13/162,883.

Referring to FIG. 8, illustrative temperature compensated BAW resonator 801 includes acoustic stack 805 formed on substrate 810. The substrate 810 may be formed of various types of materials compatible with semiconductor processes, such as silicon (Si), gallium arsenide (GaAs), indium phosphide (InP), or the like, and which are useful for integrating connections and electronics. In the depicted embodiment, the substrate 810 includes a cavity 815 formed beneath the acoustic stack 805 to provide acoustic isolation, such that the acoustic stack 805 is suspended over an air space to enable mechanical movement. In alternative embodiments, the substrate 810 may be formed with no cavity 815, for example, using SMR technology. For example, the acoustic stack 805 may be formed over an acoustic mirror or a Bragg Reflector (not shown), having alternating layers of high and low acoustic impedance materials, formed in the substrate 810. An acoustic reflector such as is described in U.S. Pat. No. 7,358,831 to Larson, III, et al., is contemplated for use in an embodiment directed to an SMR-based temperature compensated BAW resonator. The disclosure of U.S. Pat. No. 7,358,831 is hereby specifically incorporated by reference herein.

The acoustic stack 805 comprises a piezoelectric layer 830 disposed between a composite first electrode 820 and a second electrode 840. In the presently described representative embodiment, the composite first electrode 820 comprises multiple layers In various embodiments, the composite first electrode 820 comprises a base electrode layer 822, a buried temperature compensation layer 824, and a conductive interposer layer 832 stacked sequentially over the substrate 810. In a representative embodiment, the base electrode layer 822 or the conductive interposer layer 832, or both, comprise electrically conductive materials, such as various metals compatible with semiconductor processes, including tungsten (W), molybdenum (Mo), aluminum (Al), platinum (Pt), ruthenium (Ru), niobium (Nb), or hafnium (Hf), for example.

Notably, the material selected for the conductive interposer layer 832 should be selected to not adversely impact the quality of the crystalline structure of the piezoelectric layer 830. Stated somewhat differently, as it is desirable to provide a highly textured (well oriented C-axis) piezoelectric layer in the acoustic stack 805, it is beneficial to use a material for the conductive interposer layer 832 that will allow growth of a highly textured (well oriented C-axis) piezoelectric layer 830. Alternatively, a seed layer (not shown in FIG. 1) can be provided beneath the conductive interposer layer 832 to foster growth of a highly textured piezoelectric layer 830.

In various embodiments, the base electrode layer 822 and the conductive interposer layer 832 are formed of different conductive materials, where the base electrode layer 822 is comprises a material having relatively lower electrical conductivity and relatively higher acoustic impedance, and the conductive interposer layer 832 is formed of a material having relatively higher electrical conductivity and relatively lower acoustic impedance. For example, the base electrode layer 822 may be formed of W, and the conductive interposer layer 832 may be formed of Mo, although other materials and/or combinations of materials may be used without departing from the scope of the present teachings. In accordance with a representative embodiment, the selection of the material for the conductive interposer layer 832 is made to foster growth of highly textured piezoelectric material that comprises piezoelectric layer 830. Further, in various embodiments, the base electrode layer 822 and the conductive interposer layer 832 may be formed of the same conductive material, without departing from the scope of the present teachings.

The buried temperature compensation layer 824 is a temperature compensating layer, and is formed between the base electrode layer 822 and the conductive interposer layer 832. The buried temperature compensation layer 824 is therefore separated or isolated from the piezoelectric layer 830 by the conductive interposer layer 832, and is otherwise substantially sealed in by the connection between the conductive interposer layer 832 and the base electrode layer 822. Accordingly, the buried temperature compensation layer 824 is effectively buried within the composite first electrode 820.

The buried temperature compensation layer 824 may be formed of various materials compatible with semiconductor processes, including silicon dioxide (SiO₂), boron silicate glass (BSG), chromium oxide (Cr(x) O(y)) or tellurium oxide (TeO(x)), for example, which have “positive temperature coefficients.” As used herein a material having a “positive temperature coefficient” has positive temperature coefficient of elastic modulus over a certain temperature range; whereas a material having a “negative temperature coefficient,” has negative temperature coefficient of elastic modulus over the (same) certain temperature range.

The positive temperature coefficient of the buried temperature compensation layer 824 offsets negative temperature coefficients of other materials in the acoustic stack 805, including the piezoelectric layer 830. The positive temperature coefficient of the buried temperature compensation layer 824 can be selected to sufficiently offset negative temperature coefficients of other materials in the acoustic stack, so as to substantially provide a Zero Drift Resonator (“ZDR”).

As shown in the representative embodiment of FIG. 1, the buried temperature compensation layer 824 does not extend the full width of the acoustic stack 805. Thus, the conductive interposer layer 832, which is formed on the top and side surfaces of the buried temperature compensation layer 824, contacts the top surface of the base electrode layer 822, as indicated for example by reference number 829. Therefore, a DC electrical connection is formed between the conductive interposer layer 832 and the base electrode layer 822. By DC electrically connecting with the base electrode layer 822, the conductive interposer layer 832 effectively “shorts” out a capacitive component of the buried temperature compensation layer 824, thus increasing a coupling coefficient (kt²) of the temperature compensated BAW resonator 801. In addition, the conductive interposer layer 832 provides a barrier that prevents oxygen in the buried temperature compensation layer 824 from diffusing into the piezoelectric layer 830, preventing contamination of the piezoelectric layer 830.

Also, in the depicted embodiment, the buried temperature compensation layer 824 has tapered edges 824a, which enhance the DC electrical connection between the conductive interposer layer 832 and the base electrode layer 822. In addition, the tapered edges 824a enhance the mechanical connection between the conductive interposer layer 832 and the base electrode layer 822, which improves the sealing quality, e.g., for preventing oxygen in the buried temperature compensation layer 824 from diffusing into the piezoelectric layer 830. In alternative embodiments, the edges of the buried temperature compensation layer 824 are not tapered, but may be substantially perpendicular to the top and bottom surfaces of the buried temperature compensation layer 824, for example, without departing from the scope of the present teachings.

The piezoelectric layer 830 is formed on the top surface of the conductive interposer layer 832. The piezoelectric layer 830 may be formed of a thin film piezoelectric material compatible with semiconductor processes, such as aluminum nitride (AlN), zinc oxide (ZnO), lead zirconium titanate (PZT), or the like. The thickness of the piezoelectric layer 830 may range from about 9010 Å to about 901,000 Å, for example, although the thickness may vary to provide unique benefits for any particular situation or to meet application specific design requirements of various implementations, as would be apparent to one of ordinary skill in the art. In an embodiment, the piezoelectric layer 830 may be formed on a seed layer (not shown) disposed over an upper surface the composite first electrode 820. For example, the seed layer may be formed of Al to foster growth of piezoelectric layer 830 comprising AlN. The seed layer may have a thickness in the range of about 50 Å to about 5000 Å, for example.

The second electrode 840 is formed on the top surface of the piezoelectric layer 830. The second electrode 840 is formed of an electrically conductive material compatible with semiconductor processes, such as Mo, W, Al, Pt, Ru, Nb, Hf, or the like. In an embodiment, the second electrode 840 is formed of the same material as the base electrode layer 822 of the composite first electrode 820. However, in various embodiments, the second electrode 840 may be formed of the same material as only the conductive interposer layer 832; the second electrode 840, the conductive interposer layer 832 and the base electrode layer 822 may all be formed of the same material; or the second electrode 840 may be formed of a different material than both the conductive interposer layer 832 and the base electrode layer 822, without departing from the scope of the present teachings.

FIG. 9 depicts a functional block diagram a temperature compensated oscillator (TCO) 900 in accordance with a representative embodiment. In some embodiments, packaged devices as discussed previously herein may comprise a TCO such as TCO 900.

TCO 900 comprises an oscillator 910, a temperature sensor 920, and a temperature compensator 930. Oscillator 910 comprises a resonator 912 and a circuit 914. In some embodiments, resonator 912 is an BAW resonator, such as a film bulk acoustic resonator (FBAR), or a solidly mounted resonator (SMR).

Oscillator 910 may comprise a Pierce oscillator, or a Colpitts oscillator, or another convenient configuration. The frequency of oscillation of oscillator 910 is dependent upon the temperature of the device due to changes in component parameters as a function of temperature. To reduce this change in frequency in oscillator 910 over a temperature range, a variety of techniques have been developed. For example, by configuring oscillator 910 as a Voltage Controlled Oscillator (VCO), the frequency can be modified electronically. In that case, temperature sensor 920 can measure the temperature of oscillator 910 and temperature compensator 930 can use the measured temperature to modify a parameter (e.g., a capacitance) of oscillator 910. In that case, temperature compensator 930 receives a temperature sensing signal from temperature sensor 920 and provides a control voltage signal to circuit 914 to offset the oscillator frequency by an amount known to compensate for the change in the critical component parameters and oscillator frequency response over temperature.

In certain representative embodiments described herein, device (e.g., oscillators, resonators, etc.) frequencies may be approximately 2 GHz to approximately 4 GHz. In other embodiments, device frequencies may be approximately 600 Mhz to approximately 5 Ghz. The frequency accuracy over all process variation, aging, temperature range, Vdd, and load variation can be approximately +/−500 ppm up to approximately +/−2000 ppm for more relaxed requirements. Jitter may be low or more specifically ultra-low, on the order of approximately 10 femto-seconds or less.

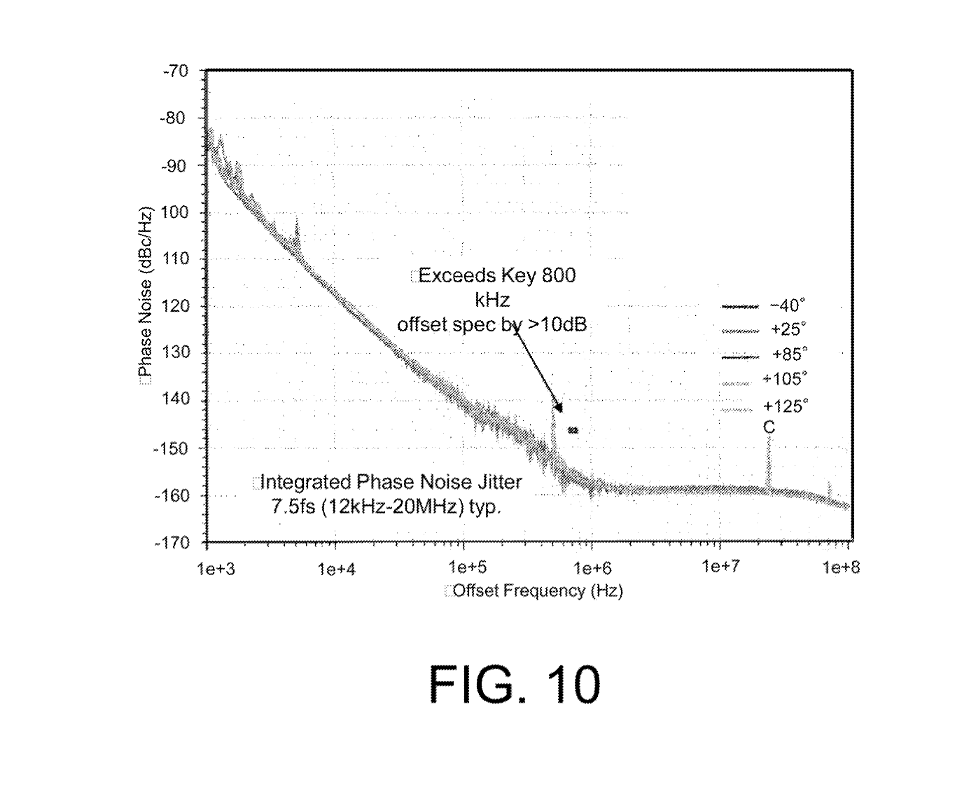

FIG. 10 shows measured phase noise plots of a 2.608 GHz FMOS Oscillator for four temperatures. The phase noise plot is measured at −40 C, 25 C, 105 C. The design specification was to meet −147 dBc/Hz at 800 KHz offset (for GSM requirements). The far-from-carrier spurs are noise picked up from the test lab and the close-in noise is from vibration from the Temptronics temperature controller.

The output signal for this device is differential and output power is typically 2 to 4 dBm for a 3.3V Vdd. Operating range of Vdd is approximately 2V to approximately 5V and the current draw at 3.3V Vdd is typically 18 mA. The 12 KHz to 20 MHz random jitter value can be 8 fs to 10 fs. The device may work comfortably up to 125° C. above that, the ESD circuits may begin to break down. Illustratively, the transistor used for this is a bipolar transistor with an ft of 25 GHz.

In another representative embodiment, an FBAR or SMR device (e.g., temperature compensated BAW resonator 101) may be used to provide a Voltage Controlled Oscillators (VCO's) in an FMOS arrangement. For demonstration purposes, a Pierce type oscillator is used (vs. the Differential Colpitts Oscillator topology used for the FRO). The base-to-resonator node may be brought out to one of the contact pads (not shown). Here, an external varactor may be connected in shunt and may be used to pull the frequency of the free running oscillator. An integrated inductor and capacitors may be used to convert the single ended output of the Pierce topology into a differential output at the contact pads.

The FMOS VCO of a representative embodiment can provide an ultra-low phase noise reference oscillator configured to generate an ultra-high frequency reference clock signal. Table I lists the measured performance of three such VCOs running at 2 GHz, 2.5 GHz and 3 GHz. All FMOS VCO's measured in Table 1 were at Vdd=3.3 V. Idd typically was around 20 mA. It is noted that only the 2500 MHz FMOS VCO was optimized for tuning and power output.

TABLE 1

| | Output Power | Tuning | PN@ | PN@ | PN@ | | |
|---|---|---|---|---|---|---|---|
| Device | (over tuning) | Range | 10 KHz | 100 KHz | 1 MHz | jitter | comments |
| 1996 | −9 to | 1000 | −117 | −144 | −160 | 6.6 | integrated |
| Mhz | 14 dBm | ppm | dBc/Hz | dBc/Hz | dBc/Hz | fs | inductor |
| | | | | | | | not |
| | | | | | | | optimized |
| 2500 | −1 to | 2000 | −114 | −138 | −158 | 17 | Optimized |
| Mhz | 0 dBm | ppm | dBc/Hz | dBc/Hz | dBc/Hz | fs | |
| 2949 | 1 to | 400 | −105 | −130 | −150 | 35.5 | Not |
| Mhz | 2 dBm | ppm | dBc/Hz | dBc/Hz | dBc/Hz | fs | optimized |
| | | | | | | | for tuning- |
| | | | | | | | expect >1000 |
| | | | | | | | ppm |

One of the benefits that may flow from one embodiment using bipolar transistors in the lid substrate (described below) is that the close-in phase noise may be very low. The typical offset frequency where the flicker noise contribution from the oscillator circuit “kicks in” may be 100 KHz to 200 KHz for FETs. However, for bipolar transistors, the flicker noise component may start between 10 KHz and 20 KHz offset. Since the 1/f component of the flicker noise may be converted into a 1/f3 phase noise dependence, about 10 dB per decade better phase noise close-in may be exhibited starting from approximately 100 KHz to approximately 10 KHz for bipolar transistors. On the resonator side, the AlN piezoelectric layer of the FMOS VCO may have the unusual ability to handle large amounts of power without going non-linear. In certain representative embodiments, comparatively low-jitter oscillators with up to 90 mA of displacement current generated in the device. The ability to ‘dump’ large amounts of power into the FMOS VCO may provide a very low far-from-carrier phase noise floor.

Since jitter is the integrated phase noise of the VCO, the far-from-carrier noise floor and the lower close-in phase noise contributions from the bipolar transistor may achieve superior jitter. As described in the above sections, sub-10 femto-second jitter is exhibited in designs (where the limits of the integrated jitter are from 12 KHz to 20 MHz). Of course, there may be limitations as to what kinds of circuits that can be constructed using bipolar transistors. If digital logic is needed, then there may be design trade offs as to some of that jitter performance in exchange for more flexibility.

For example, in contrast to bipolar, devices may be implemented in CMOS technology. There may be some degradation of the jitter when replacing the bipolar transistor with a FET, but there may also be some added benefits from added digital circuitry. For example, a “wish list” of functions to add to the fundamental oscillator can be created. Among these may be the ability to “fine tune” the output frequency to compensate for process variations and inadequacy or limitation of the ion mill tools to achieve fine frequency adjustments. Beyond that, one might ask for a Low voltage Drop Out (LDO) to eliminate or mitigate frequency pulling due to variations in the supply voltage, and “bullet-proof” ESD circuits to cover usage in hostile environments. Dividers would be desired, along with a library of output drifves (LVDS, PECL, CML . . . ). Even an All Digital PLL (ADPLL) may be employed to provide a variety of frequency products.

As a fixed frequency oscillator, dimensions of the fixed frequency oscillator a may be approximately 1×1 mm² (square millimeters) with a height of approximately 0.23 mm (millimeter). This device may comprise a sealed oscillator using an FBAR as the high Q resonator. The external 1×1 mm2 package may comprise six pads and may be coupled and/or integrated with an Application Specific Integrated Circuit (ASIC) using standard Surface Mount Technology (SMT) assembly techniques. As a proof of concept, a 2.5 GHz differential output oscillator design was realized and tested. A low mean random jitter of approximately 7.5 femtoseconds—12 KHz to 20 MHz—(sample size was >10,000) was observed. The fundamental frequency was approximately 2.608 GHz. A low mean phase noise at approximately 800 KHz offset may be approximately −157 dBc/Hz. Typical drift over industrial temperature ranges may be less than +/−100 ppm (parts per million). The design may be substantially all-silicon, may be packaged, and may comprise a high frequency oscillator with potential use in high speed SERDES (SERializer/DESerializer) and/or fiber optic communications. Accordingly, the foregoing may provide a substantially all-silicon packaged oscillator, which may use FBAR resonators, and which may be combined with IC circuits integrated into a package, which may have dimensions of approximately 1×1 mm2 with a height of approximately 0.2 mm.

The foregoing device may be implemented so as to be substantially agnostic as to what ‘flavor’ of integrated circuit used. Such advantages may flow from embodiments of the device comprising two silicon die (bonded together using wafer-bonding techniques), one holding the resonator, the other holding the integrated circuit. The base wafer may contain the resonator, which may comprise a FBAR device. Dimensions of the die may be about 0.3 mm² by 0.23 mm in height.

Filters may comprise one or more FBAR devices. For example, filters may combine four (4) to 14 FBARs (of varying frequency) in such a way that only selected frequencies may pass through the filter. Frequencies outside the pass band may be heavily attenuated. FBAR filters may be small, for example four FBAR filters may fit on a grain of rice. The actual resonators are inside these die. The silicon lid wafer supports the various contacts using through vias and connections are made to the FBAR resonators on the base.

Although device embodiments of an ultra small oscillator working at Giga-Hertz frequencies with sub-10 fs jitter are particularly described herein, the following provides a more general discussion of features of this technology. As discussed previously herein, an FBAR resonator may comprise a very thin piezoelectric layer (typically aluminum nitride—AlN) sandwiched between two electrodes (typically molybdenum). The structure may have some similarities to a thin film capacitor. However, it should be understood that for the FBAR, piezoelectric material may convert ac voltage presented across the electrodes into physical motion. The sound waves generated in the bulk of the piezo layer may be trapped by the two air interfaces on each side of the device (hence, “free-standing”). The resultant device may provide a cavity that traps high frequency phonons. This cavity may have a very high Quality factor and, due to thin film process techniques, the thickness may be very thin and the resulting resonating frequencies may be very high (from approximately 0.5 GHz to greater than approximately 10 GHz).

It is also worth noting that in the particular application of filters for cell phones, there may be a premium placed on the insertion loss and rejection of filters, especially at the antenna. In some embodiments these filters, referred to as duplexers, may separate incoming frequency from outgoing frequencies. In many cases, the incoming signal strength can be as low as −113 dBm, whilst the phone is blasting power at the output (same antenna) at 24 dBm. It may be very hard to keep the transmitted signal from contaminating the receive chain. The difficulty may be further compounded by the Tx and Rx bands often being very close to each other in frequency space (often only 10's of MHz apart). Hence, the duplexer may be required to handle high powers (on the order of 30 dBm), may be required to have excellent insertion loss, may be required to have high rejection and isolation and may be required to have very steep skirts. These properties in a duplexer may be very important to the cell phone affecting battery life, number of dropped calls, etc. Hand set manufacturers may be willing to pay for the better performance. “Q” or quality factor of the resonator may be one of the key parameters that may drive performance of a filter/duplexer.

Features of sealed packaging, high Q, small size and high volume manufacturing may be good starting points, guiding use of an FBAR resonator for time and frequency applications. Temperature compensation as described herein may help to overcome one problem with standard FBARs, which may otherwise have a temperature coefficient of frequency (TCF) of about −30 ppm/C. The operating temperature range for filter/duplexers in a cell phone may be about −40 to 85 C (industrial temperature range). Beyond that, the filter may be required to handle another 30 C due to self heating and heat emanating from nearby power amplifiers and base band microprocessors. In such circumstances, the resulting full range may otherwise lead to +/−2400 ppm of frequency shift. Fortunately, for most filter applications, this shift can be tolerated. However, a new frequency band, Band 13, may no longer tolerate this variation.

This has led our work towards developing a zero drift resonator (ZDR) as discussed in detail previously herein. Temperature compensation comes in the form of a thin oxide layer added to the stack. This oxide layer has a positive Temperature Coefficient of Frequency (TCF) as compared to a negative TCF for the electrodes and the piezoelectric.

The acoustic stack can be designed such that the linear dependence of frequency vs. temperature may be substantially negligible. That said, higher order terms may be present, most notably, the quadratic term, β, and to a lesser extent, the third order term, γ. For some embodiments of acoustic stack designs, the total frequency shift may be less than approximately +/−100 ppm over the industrial range.

Features of hermeticity, high Q, small size and high volume manufacturing may be good starting points, guiding use of an FBAR for time and frequency applications. Temperature compensation as described herein may help to overcome one problem with standard FBAR, which may otherwise have a temperature coefficient of frequency (TCF) of about −30 ppm/C. The operating temperature range for filter/duplexers in a cell phone may be about −40 to 85 C (industrial temperature range). Beyond that, the filter may be required to handle another 30 C due to self heating and heat emanating from nearby power amplifiers and base band microprocessors. In such circumstances, the resulting full range may otherwise lead to +/−2400 ppm of frequency shift.

As can be appreciated, a temperature compensated BAW resonator, such as described above, provides improved performance through a reduced frequency shift. The acoustic stack can be designed such that the linear dependence of frequency vs. temperature may be substantially negligible. That said, higher order terms may be present, most notably, the quadratic term, β, and to a lesser extent, the third order term, γ. For some embodiments of acoustic stack designs, the total frequency shift may be less than approximately +1-100 ppm over the industrial range.

In light of all of the foregoing, it should be understood that some embodiments may provide: 1) a modified FBAR resonator, the ZDR; 2) a sealed packaged part in a very small form factor; 3) Q that may range from 2500 to 5000 and an f*Q product that may be within a factor of 10 of typical Quartz resonators; and 4) parts that may be manufacturable in high volumes.

The rather daunting challenge of having to qualify a resonator led to the idea of placing the oscillator circuitry into the lid wafer (that is used to form the sealed cavity). By doing so, an impedance measurement is replaced with a frequency measurement. Using reliable frequency counters tied to a Stratum 1 timing source, any drifts due to measurement errors could be substantially eliminated during the six to 12 months that it takes to qualify a part.

Furthermore, since the resonator and oscillating circuit are in intimate contact and connected by solid silicon connections (or ‘drop downs’), the device is far more resistant to vibration and acceleration compared to oscillators that use discrete resonators connected using wire bonds and held by epoxy.

The figures show the base wafer die (with resonator) and the lid wafer (with circuitry). FMOS devices with both CMOS and with bipolar circuitry in the lid have been processed and tested. The larger via pads seen on the base die connect up through the silicon to pads on the outside of the finished device. The smaller via pads connect the resonator to the IC circuitry.

Unlike a resonator, the assembled and bonded wafers can be tested for frequency on wafer. This means that large numbers of devices (approximately 15,000 to 40,000 oscillators per wafer) can be tested against a frequency counter tied to a Stratum 1 reference clock for valid statistics. Besides frequency, we can also gather information on the phase noise and jitter of each oscillator using a 5052B Signal Source Analyzer.

In some embodiments, a single package design (via locations, pedestal size, standoffs etc. . . . ) may be employed. IC designers may fit their circuit within the pedestal area. Once that package is fully qualified (applying the most strenuous conditions possible), subsequent changes to the circuitry (even replacing bipolar with CMOS circuitry) may only require a product qualification rather than a re-qualification of the whole package.

In one embodiment, on the bottom side of the die, six copper SMT solderable connection pads may join to six vias. The six pads may have an ENIG (Electroless plated Nickel with Gold finish)-prepared surface and can be assembled alongside standard SMT components (e.g. inductors, capacitor). On the top side, laser markings may identify the die, the wafer lot and assembly lot for traceability.

In a representative embodiment, in a packaged FMOS device, the first BAW resonator may comprise an ultra high frequency resonator, and in particular may comprise an S band resonator. The BAW resonator may comprise an ultra low phase noise resonator. The electronic circuitry and the BAW resonator may comprise an oscillator, and in particular may comprise an ultra high frequency oscillator and/or an S band oscillator. The electronic circuitry and the BAW resonator may comprise an ultra low phase noise oscillator.

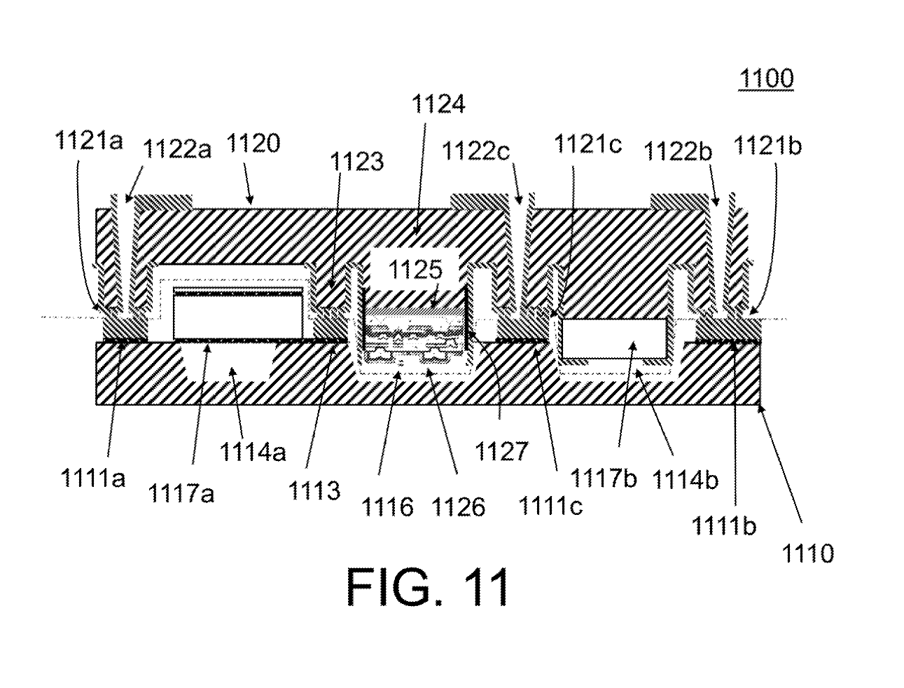

FIG. 11 shows another representative embodiment of a packaged device with two BAW resonators.

Packaged device 1100 comprises a base substrate 1110 and a lid substrate 1120.

Base substrate 1110 has on a first surface (top surface as shown in FIG. 11) thereof: first bonding pads 1111a a 1111b and 1111c; a second bonding pad 1113; and first and second and third recessed regions 1114a and 1114b and 1116. Base substrate 1110 further includes on the first surface thereof a peripheral pad not shown in FIG. 11, but examples of which are illustrated in FIGS. 5 and 6A above. Beneficially, first bonding pads 1111 and second bonding pad(s) 1113, and the peripheral pad are formed of an electrically conductive (e.g., metal) material. Also, in some embodiments base substrate 1110 may include additional first and second bonding pads 1111 and 1113.

Lid substrate 1120 has on a first surface (bottom surface as shown in FIG. 11) thereof: bonding pad seals 1121a, 1121b and 1121c, each having a corresponding through hole 1122a, 1122b and 1122c formed in lid substrate 1120; a drop down contact post 1123; a pedestal 1124; a low-resistivity material layer region 1125; and electronic circuitry 1126 formed on low-resistivity material layer region 1125. Lid substrate 1120 further includes on the first surface thereof a peripheral pad seal not shown in FIG. 11, but examples of which are illustrated in FIGS. 5 and 6B. Beneficially, bonding pad seals 1121a, 1121b and 1121c and drop down contact post 1123 each have an electrically conductive (e.g., a metal such as gold) layer thereon for making contact with the corresponding first and second bonding pads 1111 and 1113. Also, in some embodiments lid substrate 1120 may include additional bonding pad seals 1121 and/or additional drop down contact posts 1123. In some embodiments, one or more of through holes 1122 in lid substrate 1120 are plated or otherwise filled with a conductive material (e.g., metal) to provide an electrical connection between the metal layer of a corresponding bonding pad seal 1121 and a second surface (top surface as shown in FIG. 11) of lid substrate 1120, for example a pad on the second surface of lid substrate 1120. As shown in FIG. 11, in some embodiments, bonding pad seals 1121 and/or drop down contact posts 1123 include treads or gaskets that are covered with the electrically conductive material.

Packaged device 1100 further comprises first and second BAW resonators 1117a and 1117b. A first one 1117a of the BAW resonators (e.g. first BAW resonator 1117a) may be disposed on base substrate 1110 above corresponding first recessed region 1114a. Similarly a second one 1117b of the BAW resonators (e.g. second BAW resonator 1117b) may be disposed on lid substrate 1120 above corresponding second recessed region 1114b. In some embodiments, first and second BAW resonators 1117a and 1117b are each electrically connected to electronic circuitry 1126, for example by means of first and/or second bonding pads 1111, 1113 and the conductive (e.g., metal) layer on bonding pad seal(s) 1121 and/or drop down contact post 1123.

In some embodiments, each of the first and second BAW resonators 1117a and 1117b comprises a film bulk acoustic resonator (FBAR). In other embodiments, a solidly mounted resonator (SMR) may be employed. In yet other embodiments a surface acoustic wave resonator (SAW) may be employed. In contrast to a film bulk acoustic resonator (FBAR) or solidly mounted resonator (SMR), in a surface acoustic wave resonator acoustic waves are focused such that they travel along the surface of the resonator and not into the bulk of the resonator. In the surface acoustic wave resonator (SAW), these surface waves may be created by surface metal traces overlapping some amount of length, e.g. fingers or interdigitated fingers, wherein alternating voltages may be applied to alternating fingers.

In other words, more generally, the first BAW resonator 1117a, or the second BAW resonator 1117b, or both, may be a film bulk acoustic resonator (FBAR). The first BAW resonator 1117a, or the second BAW resonator 1117b, or both, may be a surface acoustic wave resonator (SAW). In the embodiment shown in FIG. 11, the first BAW resonator 1117a mounted on the base substrate 1110 may be a film bulk acoustic resonator (FBAR), while the second BAW resonator 1117b mounted on the lid substrate 1120 may be a surface acoustic wave resonator (SAW). However, in another embodiment, rather than first BAW resonator 1117a mounted on the base substrate 1110 a surface acoustic wave (SAW) resonator, with the second BAW resonator 1117b (e.g., an FBAR) mounted on the lid substrate 1120. Since differing processing steps and/or differing materials may be employed in the film bulk acoustic resonator (FBAR) and the surface acoustic wave resonator (SAW), there may be processing advantages in processing FBAR and SAW separately, each mounted on separate respective base and lid substrates, prior to assembly of the lid substrate together with the base substrate. For example, the film bulk acoustic resonator (FBAR) may comprise aluminum nitride or aluminum scandium nitride and may be mounted and/or processed initially on the base substrate, while the surface acoustic wave resonator (SAW) may comprise lithium tantalate and may be mounted and/or processed initially on the lid substrate, prior to assembly of the lid substrate together with the base substrate.

The first BAW resonator 1117a and the second BAW resonator 1117b may each have respective coupling coefficients kt² that are substantially different from one another. For example, the film bulk acoustic resonator (FBAR) may have a first coupling coefficient kt² that is substantially lower than a second coupling coefficient kt² of the surface acoustic wave resonator (SAW). The acoustic resonators of the present representative embodiment may each have respective fundamental resonant frequencies that are substantially different from one another. For example, an film bulk acoustic resonator (FBAR) may be used for first BAW resonator 1117a and the second BAW resonator 1117b may replaced by a SAW resonator. In such a case, the resonant frequency of the FBAR would be substantially higher than a second resonant frequency of the SAW resonator.

In some embodiments, electronic circuitry 1126 includes one or more transistors or other active devices for two oscillators that operate respectively with first and second BAW resonators 1117a and 1117b. In some embodiments, electronic circuitry 1126 may include one or more other elements, including for example a first mixer, a diplexer, a second mixer and/or filter.

In some embodiments, base substrate 1110 and/or lid substrate 1120 comprise a semiconductor substrate. In some embodiments, lid substrate 1120 can be made of an electronically non-conductive material or a high-resistivity semiconductor material, such as single crystal silicon. Accordingly, it should be understood that, for example, lithium tantalate of a surface acoustic wave resonator (SAW) (replacing second BAW resonator 1117b) may be mounted over (or more generally coupled with) lid substrate 1120 comprising silicon, so as to provide a silicon SAW assembly. Also, in some embodiments when lid substrate 1120 is a semiconductor substrate, low-resistivity material layer region 1125 comprises an epitaxial layer formed on the semiconductor substrate. In alternative embodiments, lid substrate 1120 may comprise other high-resistivity materials, for example a silicon-on-insulator (SOI) substrate, and low-resistivity material layer region 1125 may be formed by controlled doping of the SOI substrate.

In some embodiments, base substrate 1110 and lid substrate 1120 are made of materials that have the same or approximately the same coefficient of thermal expansion (CTE) as each other to avoid thermal expansion mismatch problems. In some embodiments base substrate 1110 and lid substrate 1120 are made of the same semiconductor material as each other.

As noted above, in some embodiments lid substrate 1120 is often a semiconductor substrate. In general, such a semiconductor substrate on which electronic circuitry 1126 is to be fabricated will have a low-resistivity material layer disposed on all or substantially all of a surface thereof for the formation of the semiconductor or active devices of electronic circuitry 1126. In particular, such a low-resistivity material layer comprises a material that has a substantially lower resistivity than the high-resistivity semiconductor material of lid substrate 1120. As used herein, “substantially lower resistivity” means about one order of magnitude lower resistivity, or more than one order of magnitude lower resistivity, for example as measured in terms of Ω-cm. For example, in some embodiments, the high-resistivity semiconductor material of lid substrate 1120 has a resistivity of more than 10 Ω-cm, while the low-resistivity material of a low-resistivity material layer has a resistivity of less than 100 Ω-cm, including in some embodiments a resistivity in a range of 10 Ω-cm. Accordingly, if left intact on lid substrate 1120, such a low-resistivity material layer may provide a low impedance path or electrical short between the conductive (e.g., metal) layer(s) of bonding pad seals 1121 and/or drop down contact post(s) 1123. This can degrade the performance of packaged device 1100, and in some cases may render packaged device 1100 inoperable.

Accordingly, in some embodiments one or more portions of the low-resistivity material layer is removed between bonding pad seals 1121, drop down contact posts 1123, and the peripheral pad seal so as to eliminate a current path through the low-resistivity material layer between any of the bonding pad seals 1121, drop down contact posts 1123, and the peripheral pad seal. Furthermore, in some embodiments one or more portions of the low-resistivity material layer are removed so as to eliminate a current path between low-resistivity material layer region 1125 and the conductive layer(s) of some or all of the bonding pad seals 1121, and/or drop down contact posts 1123, and/or the peripheral pad seal.

In a particular embodiment of packaged device 1100 shown in FIG. 11, the low-resistivity material layer (e.g., epitaxial layer) is eliminated except for: (1) low-resistivity material layer (e.g., epitaxial layer) region 1125, which is isolated from some or all of the bonding pad seals 1121, and/or drop down contact posts 1123, and/or the peripheral pad seal; and (2) one or more low-resistivity material layer (e.g., epitaxial layer) portions remaining in the treads of one or more of the bonding pad seal(s) 1121, drop down contact post(s) 1123, and the peripheral pad seal. Furthermore, lid substrate 1120 of packaged device 1100 includes an electrically insulating material 1127 (e.g., an oxide such as silicon oxide) electrically isolating low-resistivity material layer (e.g., epitaxial layer) region 1125 from one or more electrically conductive (e.g., metal) layers or traces in contact with bonding pad seal(s) 1121 and drop down contact post(s) 1123. In some embodiments, electrically insulating material 1127 partially or totally encompasses or surrounds low-resistivity material layer (e.g., epitaxial layer) region 1125.

In some embodiments, lid substrate 1120 may have a low-resistivity material layer (e.g., epitaxial layer) formed entirely on the first surface thereof, and the low-resistivity material layer (e.g., epitaxial layer)—except for low-resistivity material layer (e.g., epitaxial layer) region 1125 and the low-resistivity material layer (e.g., epitaxial layer) portions remaining in the treads—may be removed after formation of electronic circuitry 1126. In other embodiments, the low-resistivity material layer (e.g., epitaxial layer)—except for low-resistivity material layer (e.g., epitaxial layer) region 1125 and the low-resistivity material layer (e.g., epitaxial layer) portions remaining in the treads—may be removed before formation of electronic circuitry 1126.

In other embodiments, the low-resistivity material layer (e.g., epitaxial layer) is only removed in areas surrounding each of the bonding pad seals 1121, and/or drop down contact posts 1123, and/or the peripheral pad seal so as to electrically isolate the bonding pad seals 1121, and/or drop down contact posts 1123, and/or the peripheral pad seal from each other and/or from electronic circuitry 1126.

For the packaged device 1100, the lid substrate 1120 may have drop down contact post 1123 bonded to second bonding pad 1113 and providing electrical connection between first BAW resonator 1117a and the electronic circuitry 1126. Low-resistivity material layer region 1125 may be electrically isolated from the drop down contact post 1123. First and second BAW resonators 1117a, 1117b may be electrically connected with one another.

The various aspects, features, embodiments or implementations of the invention described above can be used alone or in various combinations.

For example, although not shown in FIG. 11, in the embodiment shown in FIG. 2, base substrate 210 may include additional first bonding pads 211, including corresponding through holes 212, and second bonding pads 213. In FIG. 2, one or more of the through holes 212 in base substrate 210 are plated or otherwise filled with a conductive material (e.g., metal) to provide an electrical connection between the corresponding bonding pad 211 and a second surface (bottom surface as shown in FIG. 2) thereof. Although not shown in FIG. 11, these aspects, features, embodiments or implementations described in FIG. 2 may be used in various combinations with what is explicitly shown in FIG. 11.

In other words, as an alternative to, or in addition to the through holes 1122 in lid substrate 1120, which are plated or otherwise filled with a conductive material (e.g., metal), as shown in FIG. 11, in some embodiments base substrate 1110 may include additional first bonding pads, including corresponding through holes, and second bonding pads. In some embodiments, one or more of the through holes in base substrate 1110 may be plated or otherwise filled with conductive material (e.g., metal) to provide an electrical connection between the corresponding bonding pad and a second surface (bottom surface as shown in FIG. 11) thereof.

While representative embodiments are disclosed herein, one of ordinary skill in the art appreciates that many variations that are in accordance with the present teachings are possible. The invention therefore is not to be restricted except within the scope of the claims.

What is claimed is:

1. A packaged device comprising:
a base substrate having a peripheral pad provided thereon;
a first acoustic resonator disposed on the base substrate;
a lid substrate having a peripheral pad seal provided thereon, the peripheral pad seal bonding with the peripheral pad to define a sealed volume between the lid substrate and the base substrate;
a material layer region provided on a portion of a first surface of the lid substrate within the sealed volume; and
electronic circuitry disposed over the material layer region provided on the portion of the first surface of the lid substrate.

2. A packaged device as recited in claim 1 wherein the electronic circuitry formed on the material layer region provided on the portion of the first surface of the lid substrate is electrically connected with the first acoustic resonator.

3. A packaged device as recited in claim 1 wherein: the base substrate has a first bonding pad provided thereon; and the peripheral pad encompasses the first bonding pad.

4. A packaged device as recited in claim 3 wherein: the lid substrate has a bonding pad seal; and the bonding pad seal is bonded around the perimeter of the first bonding pad.

5. A packaged device as recited in claim 3 wherein:
the lid substrate defines a through hole therein positioned over the first bonding pad; and the through hole provides access for an electrical connection to the first bonding pad.

6. A packaged device as recited in claim 3 wherein:
the base substrate defines a through hole therein positioned beneath the bonding pad; and
the through hole provides access for an electrical connection to the bonding pad.

7. A packaged device as recited in claim 3 wherein the material layer region provided on the portion of the first surface of the lid substrate within the sealed volume is electrically isolated from the bonding pad seal.

8. A packaged device as recited in claim 1 wherein the material layer region provided on the portion of the first surface of the lid substrate within the sealed volume comprises a material having a substantially lower resistivity than the lid substrate.

9. The packaged device of claim 1 wherein the first acoustic resonator is laterally offset with respect to the electronic circuitry.

10. The packaged device of claim 1 wherein the base substrate includes a first surface disposed opposite the first surface of the lid substrate, the first surface of the base substrate including at least a first recessed region disposed beneath the first acoustic resonator, and including at least a second recessed region disposed opposite the electronic circuitry.

11. The packaged device of claim 1 wherein the electronic circuitry is disposed directly opposite and confronting the first acoustic resonator.

12. The packaged device of claim 1 wherein the lid substrate is a cap semiconductor substrate, and the material layer region is an epitaxial layer region formed on the cap semiconductor substrate.

13. The packaged device of claim 1 further comprising a second acoustic resonator.

14. The packaged device of claim 13, wherein the first acoustic resonator, or the second acoustic resonator, or both, is a surface acoustic wave resonator (SAW).

15. The packaged device of claim 13, wherein the first acoustic resonator, or the second acoustic resonator, or both, is a film bulk acoustic resonator (FBAR).

16. The packaged device of claim 13, wherein the first acoustic resonator, or the second acoustic resonator, or both, is a zero drift resonator (ZDR).

17. A packaged device as recited in claim 1 wherein the electronic circuitry is coupled with the first acoustic resonator to provide an ultra low phase noise oscillator.

18. A packaged device comprising:
a base substrate having a peripheral pad provided thereon;
a lid substrate having a peripheral pad seal provided thereon, the peripheral pad seal bonding with the peripheral pad to define a sealed volume between the lid substrate and the base substrate;
a material layer region provided on a portion of a first surface of the lid substrate within the sealed volume, wherein the first surface of the lid substrate includes a pedestal; and
first and second acoustic resonators, wherein one of the first and second acoustic resonators is disposed on the base substrate.

19. A packaged device as recited in claim 18, wherein an other one of the first and second acoustic resonators is disposed on the lid substrate.

20. A packaged device as recited in claim 18 wherein:
the first acoustic resonator forms a portion of a reference oscillator;
the second acoustic resonator forms a portion of a second oscillator configured for coupling with a detector; and
differential circuitry is coupled with the reference oscillator and the second oscillator.

21. A packaged device comprising:
a base substrate having a peripheral pad provided thereon;
a lid substrate having a peripheral pad seal provided thereon, the peripheral pad seal bonding with the peripheral pad to define a sealed volume between the lid substrate and the base substrate;
a first acoustic resonator; and
a temperature compensated oscillator comprising electronic circuitry coupled with the first acoustic resonator.

22. A packaged device as recited in claim 21 wherein the first acoustic resonator comprises:
a composite first electrode disposed over a substrate, the composite first electrode comprising: a first electrically conductive layer provided over the substrate; a second electrically conductive layer disposed over the first electrically conductive layer; and a buried temperature compensating layer provided between the first and second electrically conductive layers;
a piezoelectric layer disposed over the composite first electrode, the piezoelectric layer having a negative temperature coefficient; and
a second electrode disposed over the piezoelectric layer, wherein
the buried temperature compensating layer has a positive temperature coefficient that offsets at least a portion of the negative temperature coefficient of the piezoelectric layer.
